(19) United States
(12) Patent Application Publication
(10) Pub. No.: US 2026/0143680 A1
(43) Pub. Date: May 21, 2026

(54) MICROELECTRONIC DEVICES INCLUDING DIFFUSION STRUCTURES AND RELATED MEMORY DEVICES AND ELECTRONIC SYSTEMS

(71) Applicant: Micron Technology, Inc., Boise, ID (US)

(72) Inventor: Fatma Arzum Simsek-Ege, Boise, ID (US)

(21) Appl. No.: 19/373,563

(22) Filed: Oct. 29, 2025

Related U.S. Application Data
(60) Provisional application No. 63/721,956, filed on Nov. 18, 2024.

(51) Int. Cl. H10B 12/00

(52) U.S. Cl. CPC H10B 12/33; H10B 12/036; H10B 12/05; H10B 12/50

(57) ABSTRACT

A microelectronic device includes memory array structures. Each memory array structure includes an array region comprising memory cells within a horizontal area thereof, each of the memory cells having an access device and a storage node device vertically underlying and coupled to the access device. Neighboring memory array structures border opposing horizontal boundaries of an edge of array region of the microelectronic device. The microelectronic device further includes a diffusion structure over which the memory array structures are oriented and attached. The diffusion structure including a first doped region of a semiconductor material, the first doped region horizontally overlapping the edge of array region and a second doped region of the semiconductor material, the second doped region horizontally neighboring the first doped region and at least partially surrounding outer, horizontal boundaries of the first doped region.

### CROSS-REFERENCE TO RELATED APPLICATIONS

This application claims the benefit under 35 U.S.C. § 119 (e) of U.S. Provisional Patent Application Ser. No. 63/721,956, filed Nov. 18, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device. Moreover, capacitors for regulating and supplying voltages to the control logic devices can require substantial footprints.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1A through FIG. 2D include simplified, perspective views (FIGS. 1A, 1B, 1D-1R, and 2A-2D) and a simplified, vertical cross-sectional view (FIG. 1C) of a microelectronic device structure at different processing stages of a method of forming a microelectronic device, according to one or more embodiments of the disclosure;

FIG. 3 shows a simplified, perspective view of a microelectronic device according to one or more additional embodiments of the disclosure; and

FIG. 4 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

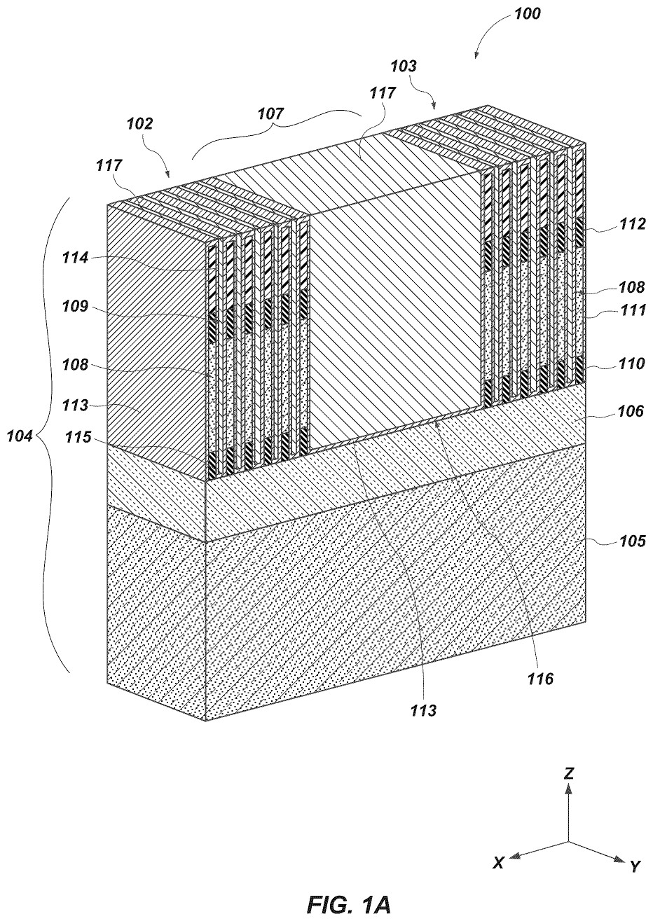

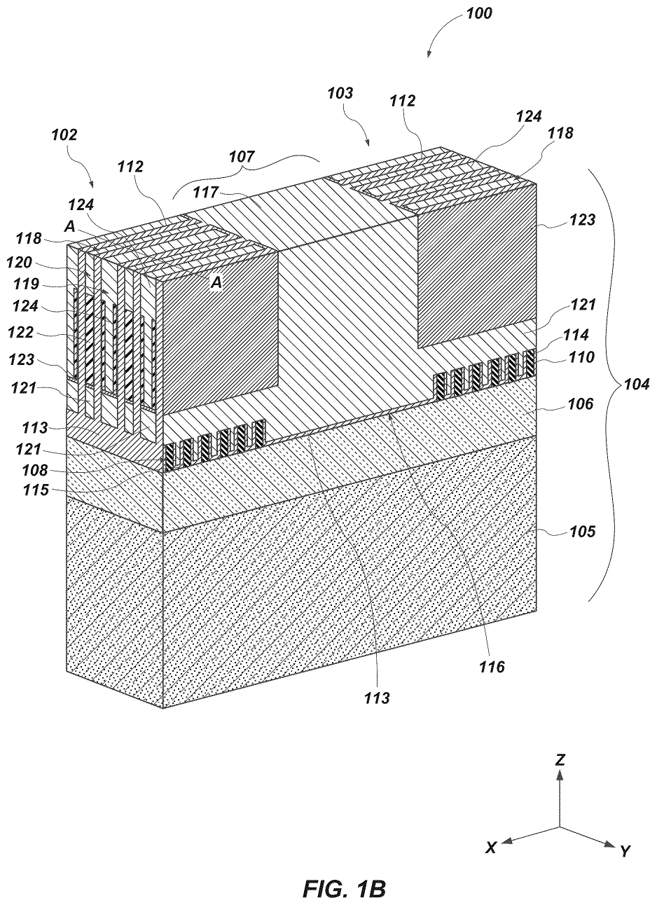

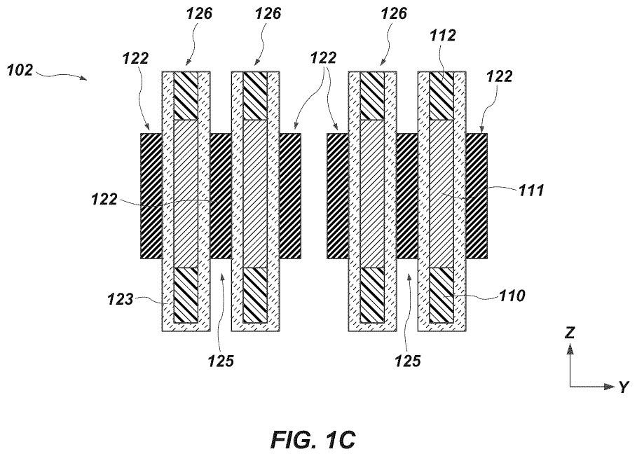

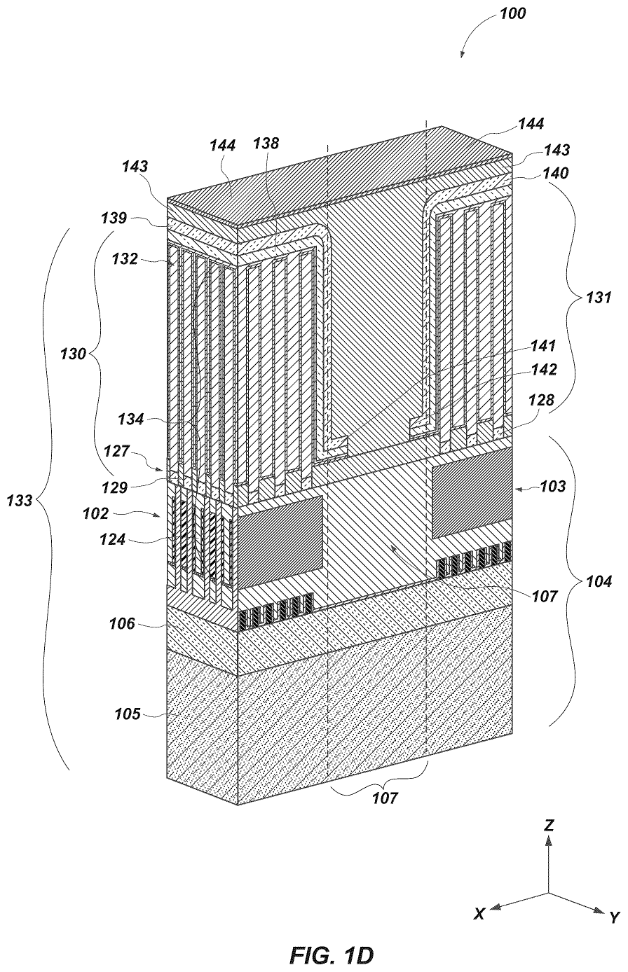

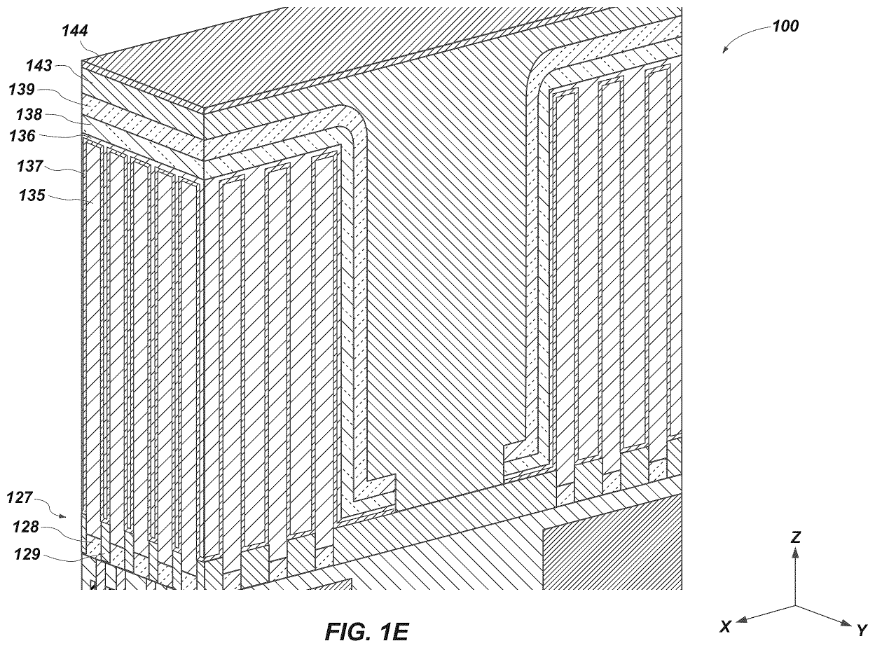

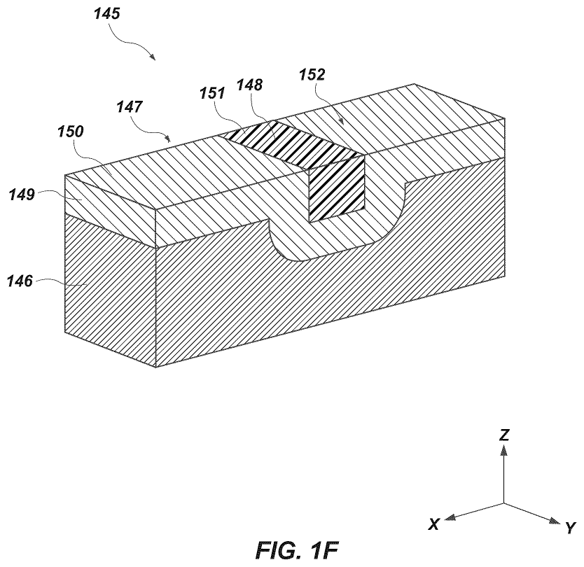

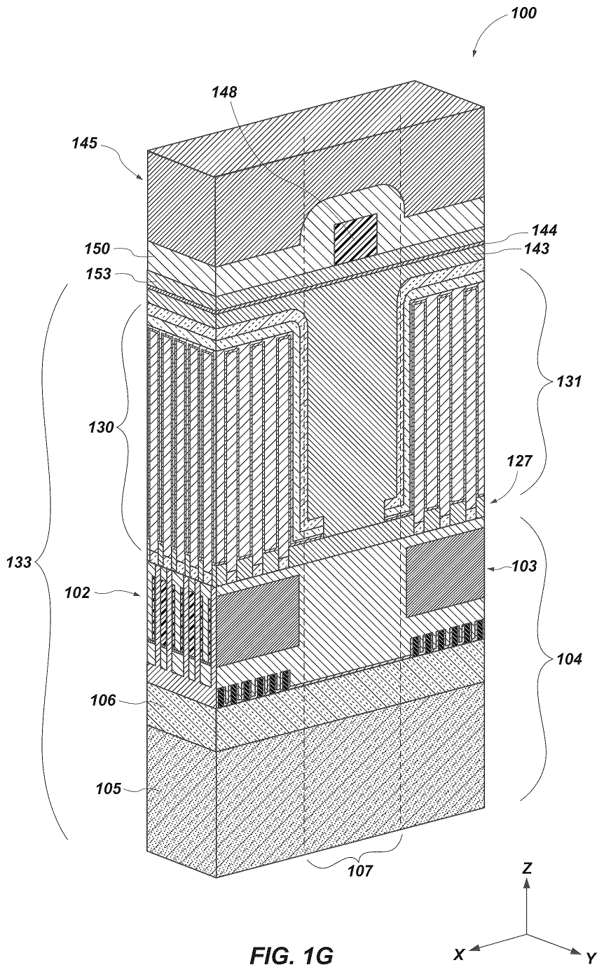

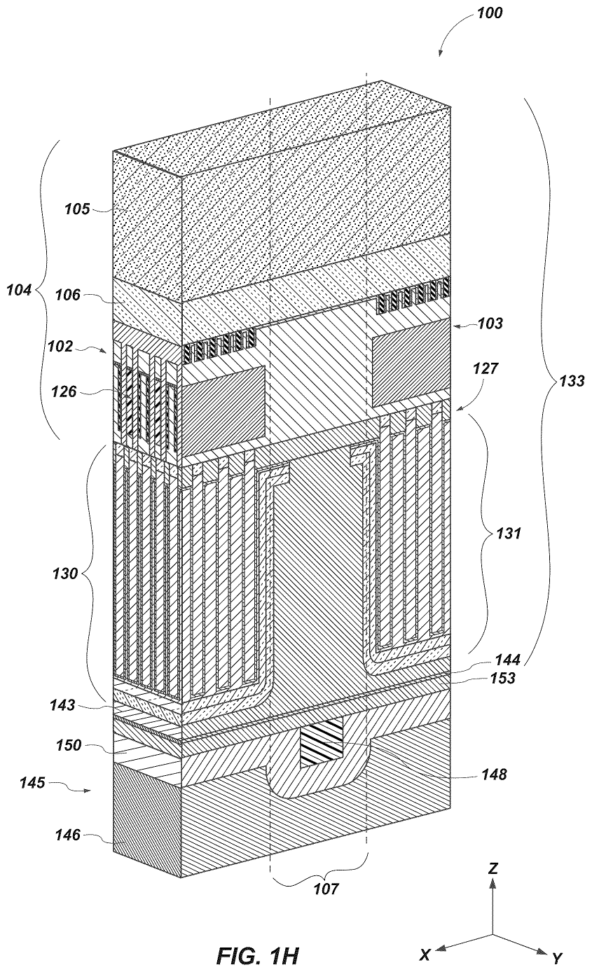

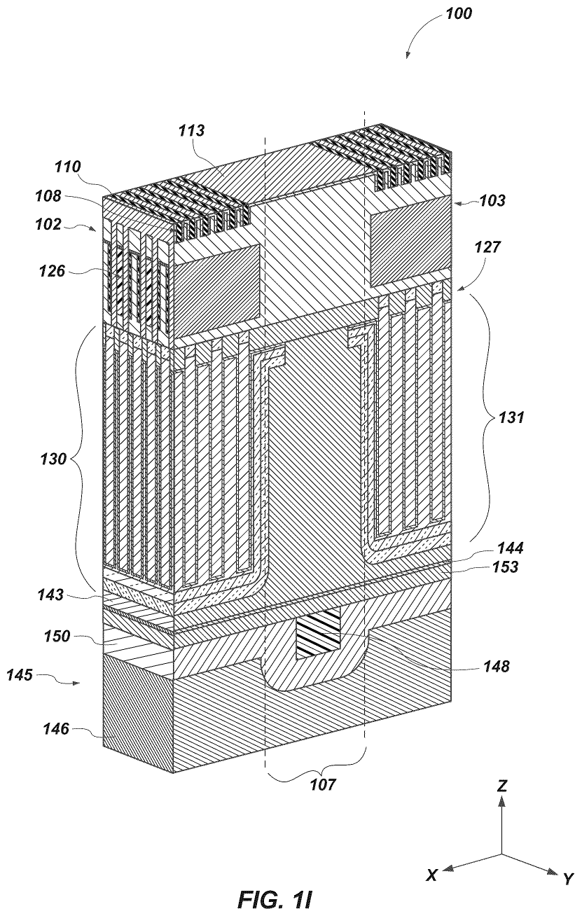

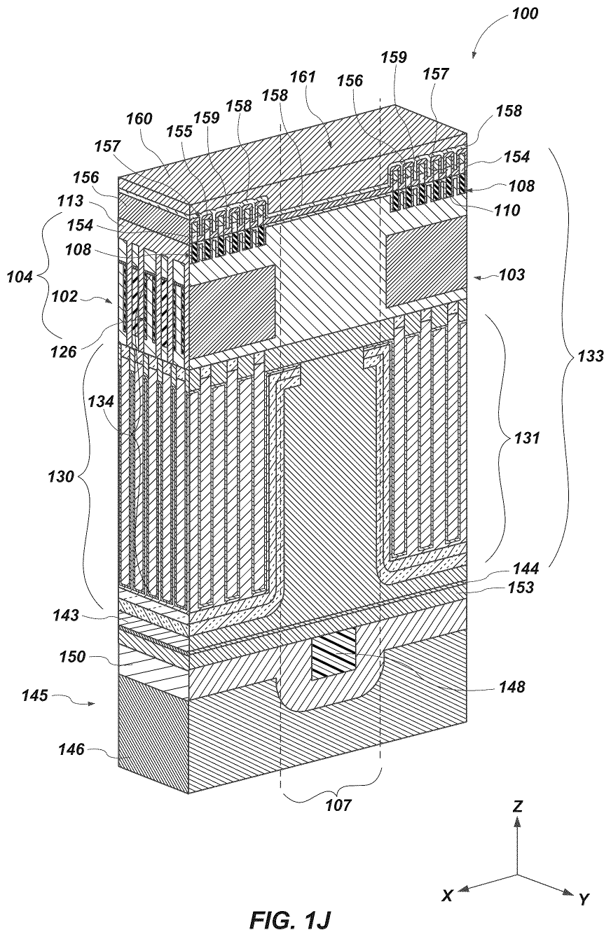

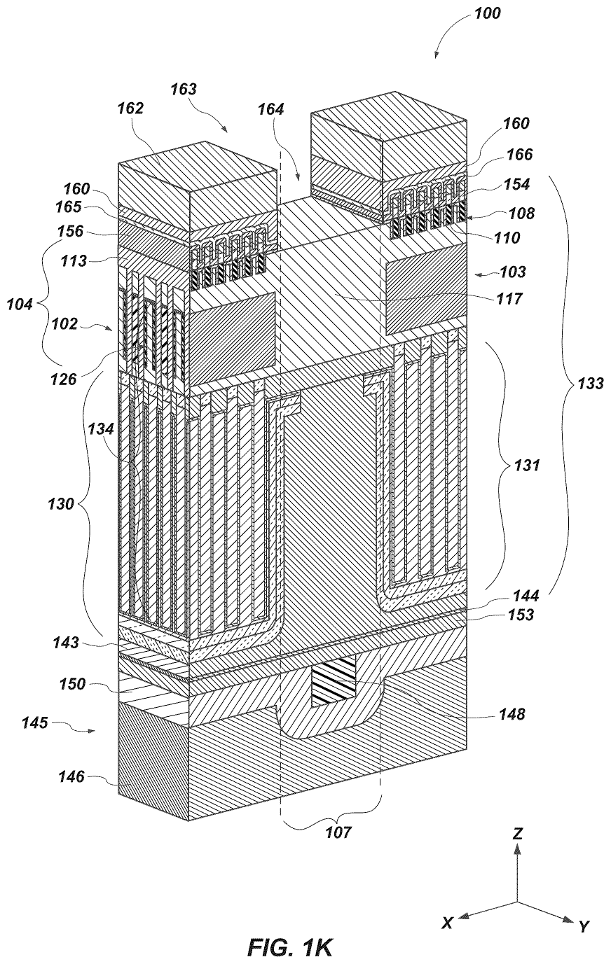

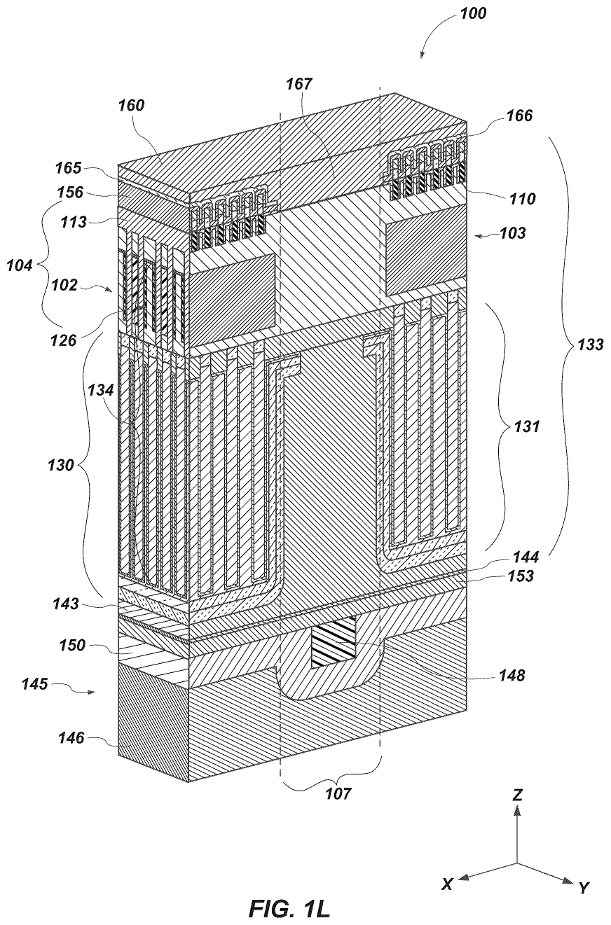

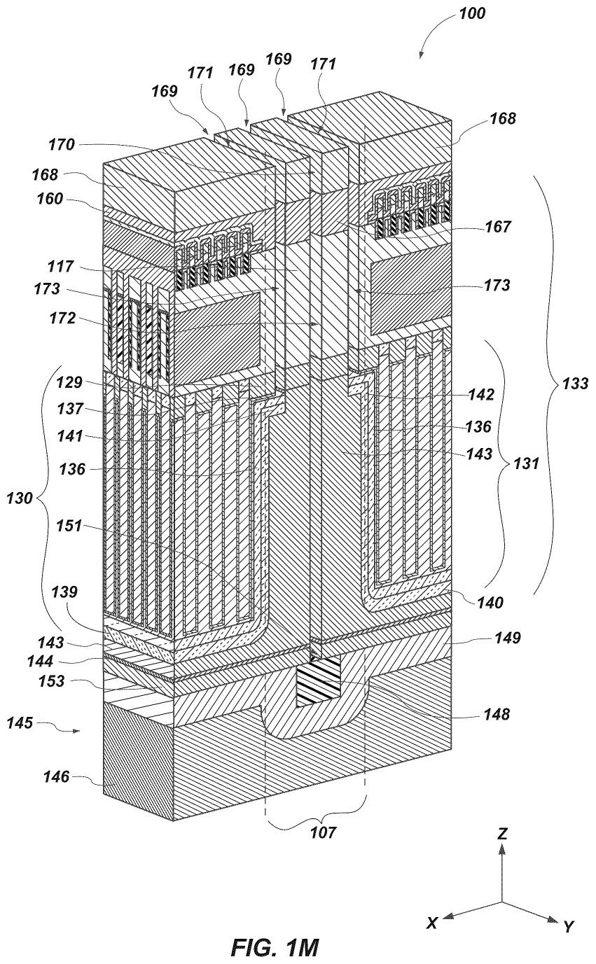

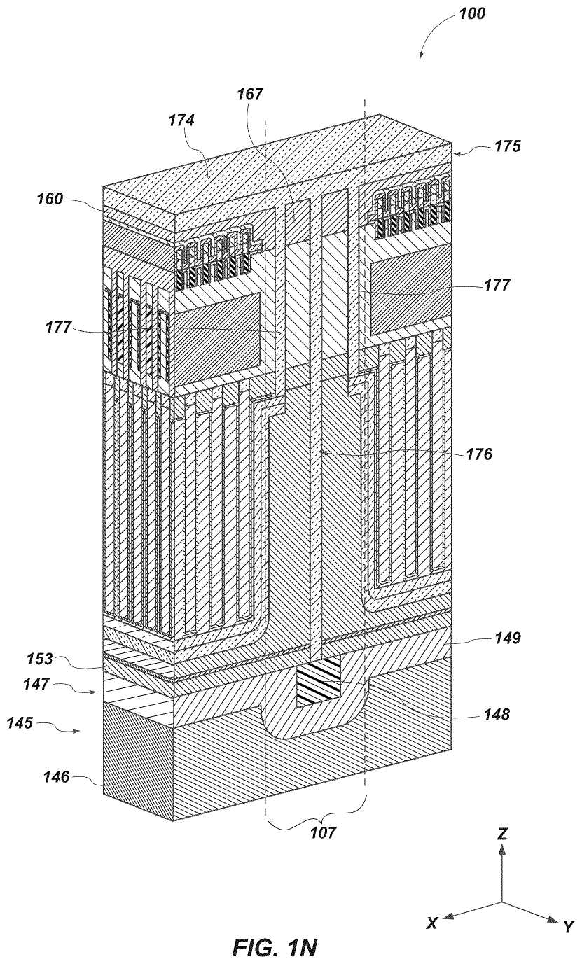

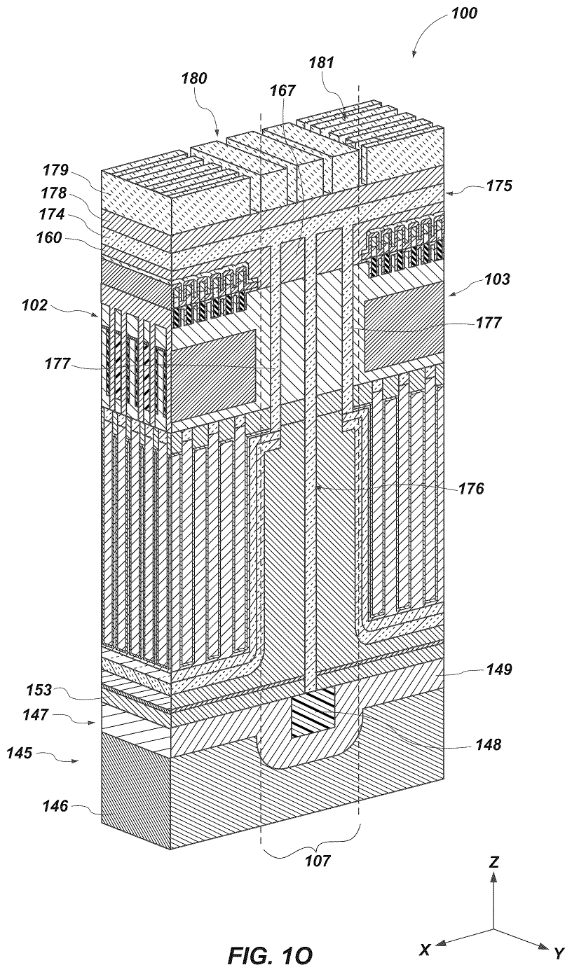

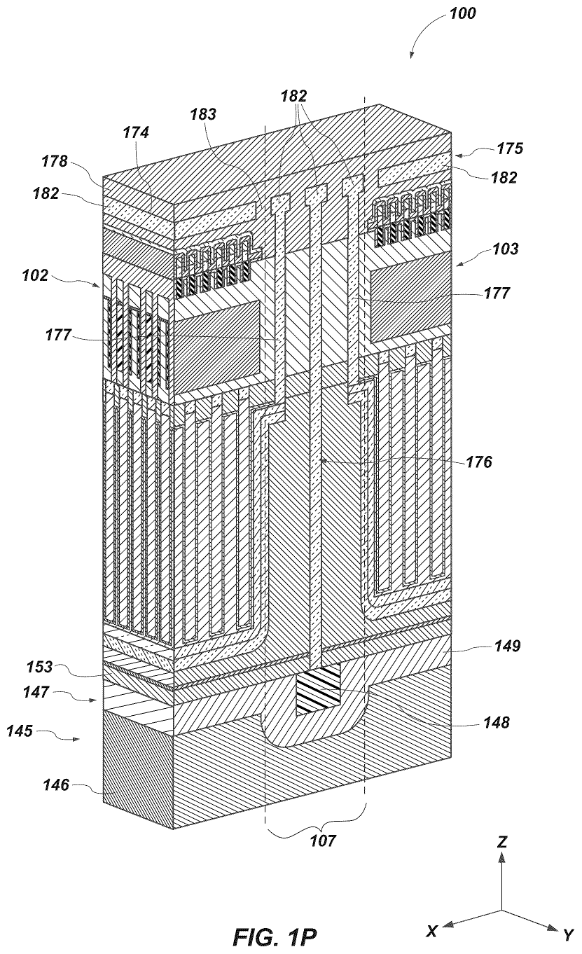

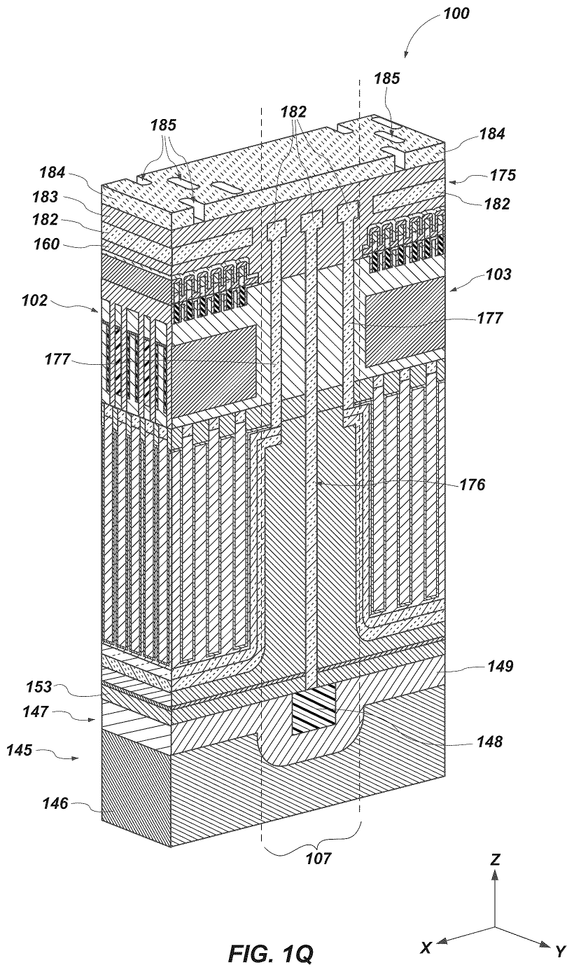

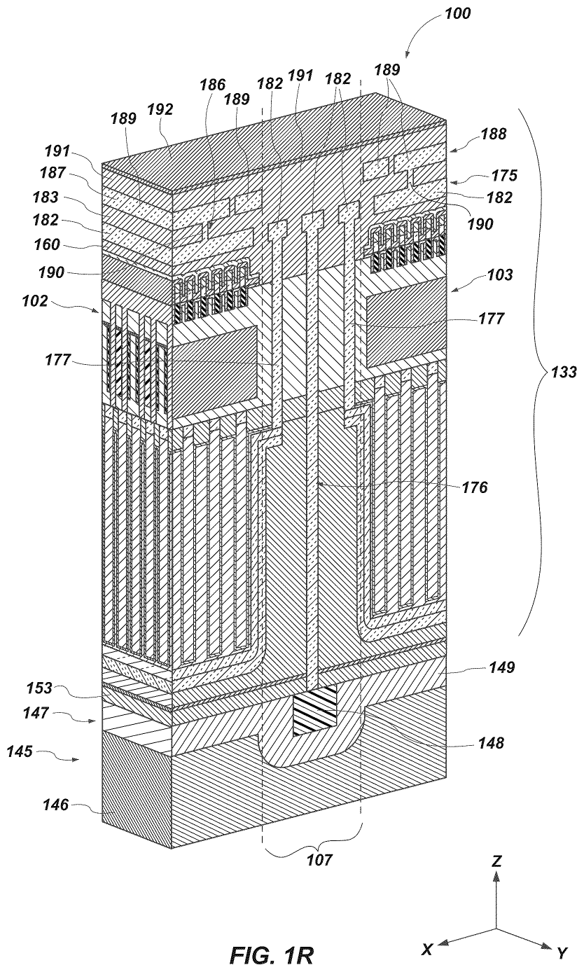

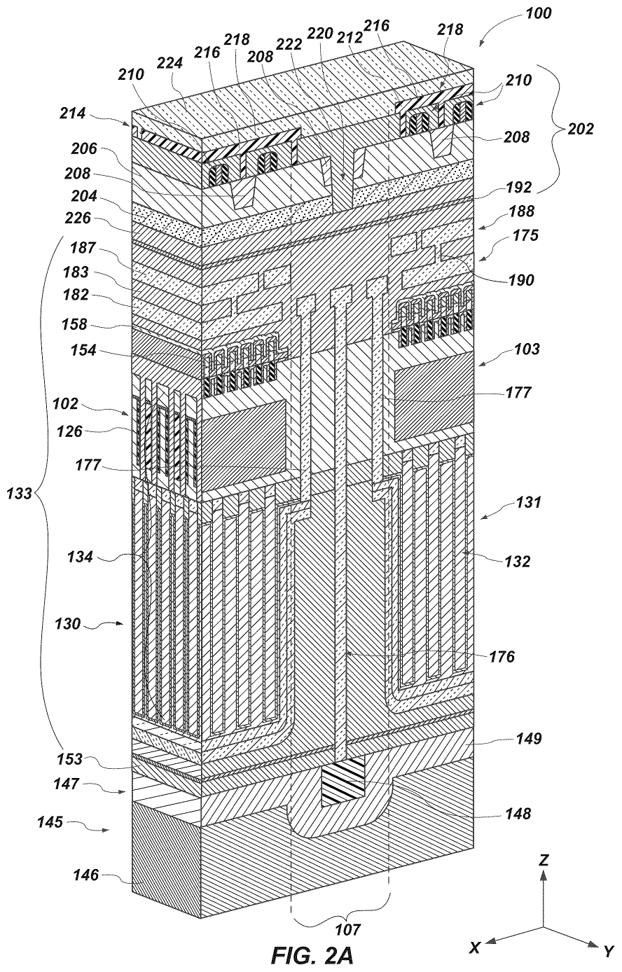

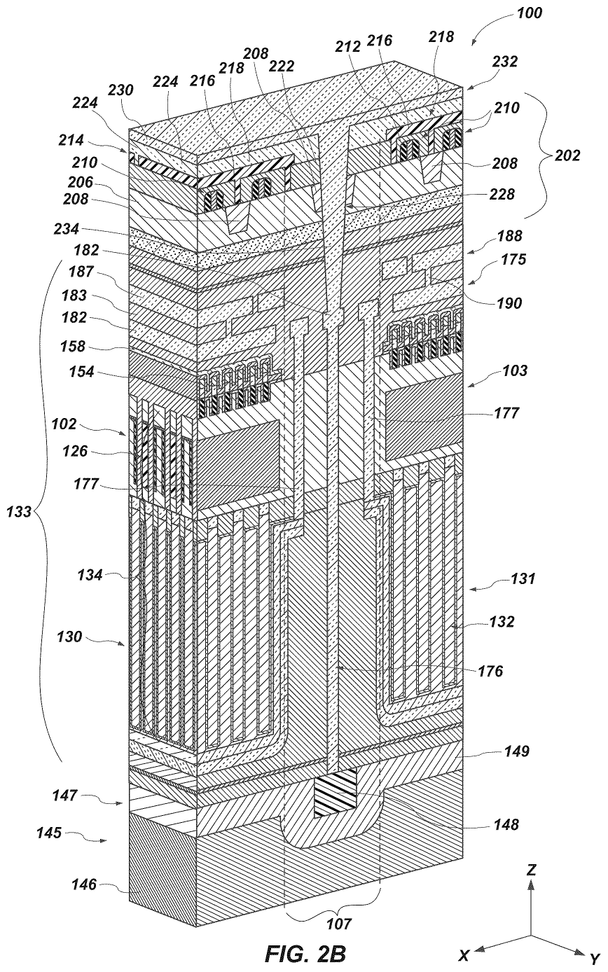

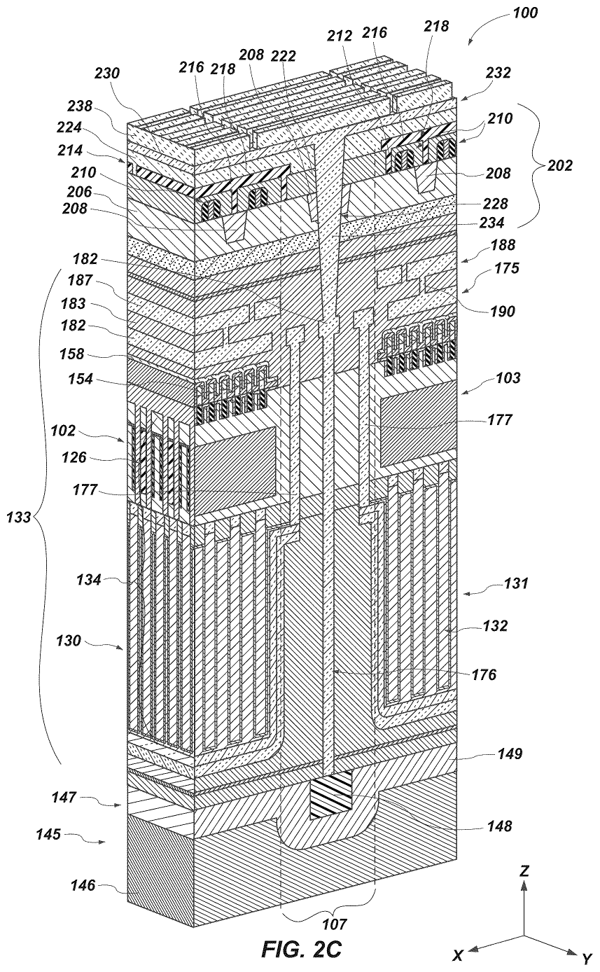

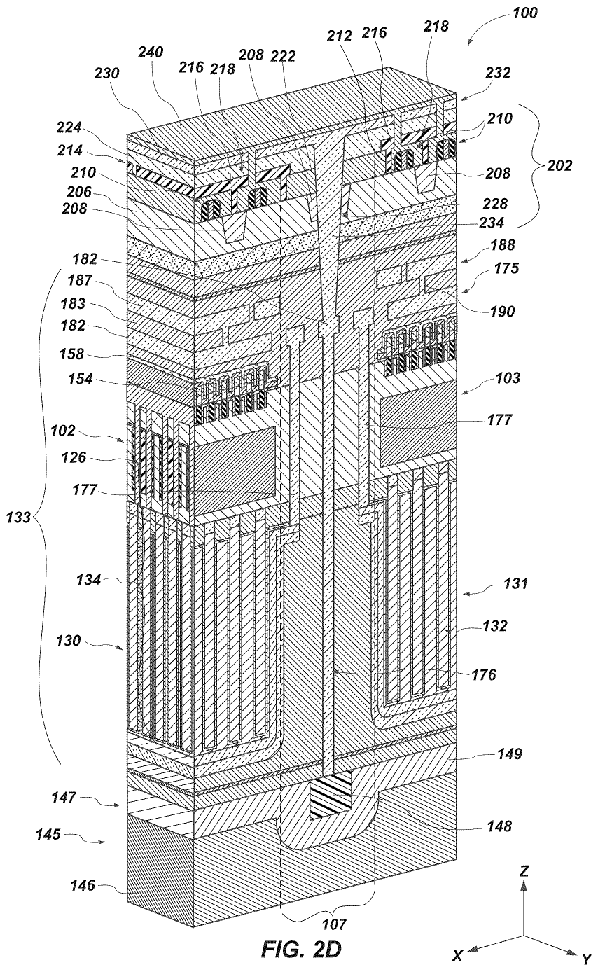

FIG. 1A through FIG. 2D include simplified, perspective views (FIGS. 1A, 1B, 1D-1R, and 2A-2D) and a simplified, vertical cross-sectional view (FIG. 1C), of a first memory array structure 102 and a second memory array structure 103 at different processing stages of a method of forming a microelectronic device 100 (e.g., a memory device, such as Dynamic Random Access Memory (DRAM) device, an HRAM device, an FeRAM device, an SDRAM device, an MRAM device), in accordance with embodiments of the disclosure. With the description provided below, it will be readily apparent to one of ordinary skill in the art that the methods described herein may be used for forming various devices.

Referring to FIG. 1A, forming the first memory array structure 102 and the second memory array structure 103 may include forming a first assembly 104. The first assembly 104 may also be referred to herein as a die or a wafer. The first assembly 104 may at least include a semiconductor structure (e.g., a semiconductor wafer) or a base semiconductive material on a support structure or construction upon which additional materials and structures of the first memory array structure 102 and the second memory array structure 103 are formed. In some embodiments, the first assembly 104 includes a first base structure 105 (e.g., a silicon substrate) and an insulative structure 106 formed on and over the first base structure 105.

The first memory array structure 102 and the second memory array structure 103 may share the first base structure 105 and the insulative structure 106. Moreover, each of the first memory array structure 102 and the second memory array structure 103 may be formed on opposing sides of an edge of array region 107 of the microelectronic device 100 in the X-direction. Put another way, each of the first memory array structure 102 and the second memory array structure 103 may horizontally neighbor and flank the edge of array region 107 of the microelectronic device 100 (e.g., edge of die) in the X-direction. In particular, the edge of array region 107 may be defined between horizontal edges of neighboring patch regions or bank regions of the microelectronic device 100. In some embodiments, the microelectronic device 100 includes a separation trench 116 formed within the edge of array region 107, filled with a first isolation material 117 (described below), and separating the first memory array structure 102 from the second memory array structure 103.

Each of the first memory array structure 102 and the second memory array structure 103 may include semiconductor projections 108 extending from an upper surface of and formed on or over the insulative structure 106. The semiconductor projections 108 may include a semiconductor material; and, together with the insulative structure 106, may form a silicon-over-insulator (SOI) substrate. The semiconductor projections 108 may be laterally spaced apart by trenches 109 extending vertically into the first assembly 104 and between neighboring semiconductor projections 108 of the first memory array structure 102 and neighboring semiconductor projections 108 of the second memory array structure 103. The trenches 109 may extend horizontally in parallel in the Y-direction (e.g., a first direction) and may be referred to herein as “y-axis trenches 109.” The y-axis trenches 109 may have any suitable dimensions. In some embodiments, the y-axis trenches 109 have vertical depths (e.g., vertical heights) within a range of from about 100 nm to about 200 nm (e.g., about 145 nm).

The semiconductor projections 108 may include silicon structures, such as epitaxial silicon structures. Additionally, each of the semiconductor projections 108 may include a first doped region 110 vertically overlying the insulative structure 106, an undoped region 111 vertically overlying the first doped region 110, and a second doped region 112 vertically overlying the undoped region 111. In some embodiments, each of the first doped region 110 and the second doped region 112 are n-type doped, such as N-type doped to an N-type dopant concentration within a range of from about 10¹⁵ cm⁻³ to about 10²⁰ cm⁻³. In additional embodiments, one of the first doped region 110 and the second doped region 112 may be N-type doped while the other of the first doped region 110 and the second doped region 112 may be P-type doped, such as P-type doped to a P-type dopant concentration within a range of from about −10¹³ cm⁻³ to about −10¹⁸ cm⁻³. In additional embodiments, one or more of the first doped region 110 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor projections 108 or a structure formed into the semiconductor projections 108. A P-type dopant may include one or more of boron, aluminum, and gallium; and an N-type dopant may include one or more of arsenic, phosphorous, antimony, and bismuth.

In some embodiments, the undoped region 111 does not include any P-type dopants or any N-type dopants. In alternative embodiments, the undoped region 111 is doped with one of the dopants described herein and becomes another doped region.

In one or more embodiments, the first doped region 110 forms a drain region of a later-formed vertical channel transistor (VCT), the undoped region 111 forms a channel region of the later-formed VCT, and the second doped region 112 forms a source region of the later-formed VCT.

The first assembly 104 may further include a first dielectric liner material 113 formed in the y-axis trenches 109 and over the semiconductor projections 108 of the first memory array structure 102 and the semiconductor projections 108 of the second memory array structure 103. The first dielectric liner material is formed over and alongside surfaces of the semiconductor projections 108 and upper surfaces of the insulative structure 106 between neighboring semiconductor projections 108. Within the y-axis trenches 109, the first dielectric liner material 113 may include side portions 114 on the side surfaces of the semiconductor projections 108, and, optionally, bottom portions 115 on or over the upper surfaces of the insulative structure 106. Within an individual y-axis trench 109, the bottom portion 115 of the first dielectric liner material 113 may be integral and continuous with the side portions 114 of the first dielectric liner material 113. In some embodiments, upper surfaces of the bottom portions 115 of the first dielectric liner material 113 are vertically offset from (e.g., are vertically below) interfaces between the first doped regions 110 and the undoped regions 111 of the individual semiconductor projections 108.

The first dielectric liner material 113 may further be formed within the separation trench 116 defined within the edge of array region 107 and between the first memory array structure 102 and the second memory array structure 103. Within the separation trench 116, the first dielectric liner material 113 overlies an upper surface of insulative structure 106 extending between the first memory array structure 102 and the second memory array structure 103 in the X-direction and within the edge of array region 107 of the first assembly 104.

The first dielectric liner material 113 may be formed of and include insulative material. In some embodiments, the first dielectric liner material 113 is formed of and includes silicon dioxide. In some embodiments, the first dielectric liner material 113 is formed (e.g., conformally deposited) inside and outside of the y-axis trenches 109 and portions of the first dielectric liner material 113 outside of the y-axis trenches 109 (e.g., on upper surfaces of the first dielectric liner material 113) remain. In additional embodiments, the first dielectric liner material 113 is formed (e.g., conformally deposited) inside and outside of the y-axis trenches 109 and then portions of the first dielectric liner material 113 are removed (e.g., by way of CMP) while additional portions of the first dielectric liner material 113 within the y-axis trenches 109 are maintained. The side portions 114 and the bottom portions 115 of the first dielectric liner material 113 may have a thickness within a range of from about 3 nm to about 7 nm (e.g., about 5 nm).

Subsequent to forming the first dielectric liner material 113, the first isolation material 117 may be formed within the y-axis trenches 109 and within the separation trench 116 within the edge of array region 107 of the first assembly 104. For instance, the y-axis trenches 109 and the separation trench 116 may be filled with the first isolation material 117. In some embodiments, the first isolation material 117 is formed of and includes a dielectric oxide material, such as SiOₓ (e.g., SiO₂). The first isolation material 117 may be substantially homogeneous, or the first isolation material 117 may be heterogeneous. The first isolation material 117 may, for example, be formed of and include a stack of at least two different dielectric materials. The first isolation material 117 may be formed (e.g., deposited) via and of the manners described herein.

Referring to FIG. 1B, additional trenches 118 may be formed to extend vertically into the first assembly 104. In particular, the additional trenches 118 may be formed to extend vertically into the semiconductor projections 108 of the first memory array structure 102 and the semiconductor projections 108 of the second memory array structure 103. The additional trenches 118 may extend horizontally in parallel in the X-direction (e.g., a second direction) perpendicular to the Y-direction and may be referred to herein as “x-axis trenches 118.”

In some embodiments, the x-axis trenches 118 are formed using a mask material and an etching process (e.g., an anisotropic etching process) that removes exposed portions of the first isolation material 117, the first dielectric liner material 113, and the semiconductor projections 108. Furthermore, the x-axis trenches 118 may be formed to terminate (e.g., have lower boundaries) within the first isolation material 117 and portions of the first dielectric liner material 113 lining side surfaces of the semiconductor projections 108. In other words, portions of the first isolation material 117, portions of the first dielectric liner material 113 lining side surfaces of the semiconductor projections 108, and the bottom portions 115 of the first dielectric liner material 113 overlying the insulative structure 106 may remain between the lower boundaries of the x-axis trenches 118 and the insulative structure 106. Accordingly, lower boundaries (e.g., bottoms) of the x-axis trenches 118 may be defined by upper surfaces of the first isolation material 117 and the first dielectric liner material 113. In some embodiments, remaining portions of the semiconductor projections 108 within the x-axis trenches 118 may be subjected to one or more further etching processes to remove the remaining portions of the semiconductor projections 108 within the x-axis trenches 118 such that the upper surface of the insulative structure 106 is exposed in portions of the x-axis trenches 118 (e.g., horizontal areas immediately neighboring the semiconductor projections 108 in y-directions). As result, semiconductor pillars may be formed from the semiconductor projections 108, and the semiconductor pillars may be distinct and discrete from each other.

In one or more embodiments, some of the x-axis trenches 118 have larger widths in the Y-direction than other x-axis trenches 118. The x-axis trenches 118 having larger widths may be referred to as “wide x-axis trenches 119” hereinafter, and the x-axis trenches 118 having smaller widths may be referred to as “thin x-axis trenches 120” hereinafter. Furthermore, in some embodiments, each of the wide x-axis trenches 119 may be formed in between two thin x-axis trenches 120.

The x-axis trenches 118 may be partially filled within a spacer material 121. In one or more embodiments, the spacer material 121 is deposited within the x-axis trenches 118 through a spin-on coating process. For instance, the spacer material 121 may include a spin-on dielectric. Furthermore, subsequent to the spin-on coating process, the spacer material 121 may be recessed (e.g., removed through an etching process (dry or wet etching process)) to leave only portions of the spacer material 121 at the bottoms of the x-axis trenches 118.

In some embodiments, the spacer material 121 is formed of and includes a dielectric oxide material, such as SiOₓ (e.g., SiO₂). The spacer material 121 may be substantially homogeneous, or the spacer material 121 may be heterogeneous. The spacer material 121 may, for example, be formed of and include a stack of at least two different dielectric materials.

The degree to which the spacer material 121 is recessed may serve to position the later-formed gate electrodes (i.e., word lines) a desired distance from the insulative structure 106 and a boundary of the first doped region 110 and the undoped region 111 (FIG. 1A) of the semiconductor projections 108. For instance, the remaining portion of the spacer material 121 may space the later-formed gate electrodes (i.e., word line structures 122 (described below)) from the insulative structure 106 and the boundary of the first doped region 110 and the undoped region 111 (FIG. 1A) of the semiconductor projections 108 by desired distances, and as a result, may space the later-formed gate electrodes (i.e., word line structures 122) from later-formed contacts and/or digit lines (discussed below). For example, the thickness of the spacer material 121 may at least partially determine a distance between the later-formed gate electrodes (i.e., word line structures 122) and a digit line junction. The remaining portion of the spacer material 121 may exhibit a thickness within a range of from about 30 nm to about 60 nm. For instance, the spacer material 121 may be etched to have a thickness of about 45 nm.

A second dielectric liner material 123 (i.e., a gate dielectric material) may be formed in the x-axis trenches 118, over the semiconductor projections 108 (i.e., pillars), over the first isolation material 117, over the first dielectric liner material 113, and over the spacer material 121 of the first memory array structure 102 and the second memory array structure 103 of the first assembly 104. The second dielectric liner material 123 may also be referred to as a gate dielectric material. The second dielectric liner material 123 is formed over and alongside surfaces of the semiconductor projections 108 (i.e., pillars), exposed surfaces of the first dielectric liner material 113, and upper surfaces of the spacer material 121.

The second dielectric liner material 123 (i.e., gate dielectric material) may be formed of and include insulative material. In some embodiments, the second dielectric liner material 123 is formed of and includes silicon dioxide. In one or more embodiments, the second dielectric liner material 123 includes a material with a relatively high dielectric constant (k) (i.e., a high-k material). In some embodiments, the second dielectric liner material 123 is formed (e.g., conformally deposited) inside and outside of the x-axis trenches 118. The second dielectric liner material 123 may have a thickness within a range of from about 4 nm to about 6 nm (e.g., about 5 nm).

As mentioned briefly above, word line structures 122 (e.g., access lines, gate electrodes, gate metal) may be formed on the second dielectric liner material 123 and within the x-axis trenches 118. The word line structures 122 may include any of the conductive materials described herein.

In one or more embodiments, the word line structures 122 are formed by at least partially filling the x-axis trenches 118 with a gate electrode material, and subsequently removing one or more portions of the gate electrode material. In some embodiments, the gate electrode material within the wide x-axis trenches 119 are recessed differently than the gate electrode material within the thin x-axis trenches 120.

As non-limiting examples, within the wide x-axis trenches 119, subsequent to depositing the gate electrode material within the x-axis trenches 118, an entirety of the gate electrode material may be recessed down to a desired upper boundary of the word line structures 122, and a center portion of the gate electrode material may be further recessed (e.g., removed) to form recesses extending vertically through the remaining gate electrode material and to the second dielectric liner material 123. As a result, two word line structures 122 separated by a respective recess may be formed within each of the wide x-axis trenches 119. Additionally, within the thin x-axis trenches 120, an entirety of the gate electrode material may be recessed down to a desired upper boundary of the word line structures 122, and the remaining gate electrode material forms a given word line structure 122. In view of the foregoing, in some embodiments, the gate electrode material in both the wide x-axis trenches 119 and the thin x-axis trenches 120 are recessed down to a desired upper boundary of the word line structures 122 during a first etching process; and the recesses are formed within remaining gate electrode material within the wide x-axis trenches 119 in a subsequent, second etching process.

The gate electrode material may be formed (e.g., deposited) through any of the manners described herein. Additionally, recessing the gate electrode material and forming the recesses in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the second dielectric liner material 123) of the first assembly 104.

The recesses may be formed to a desired width (e.g., horizonal dimension) in the Y-direction such that portions of the gate electrode material (i.e., the word line structures 122) remain adjacent to the second dielectric liner material 123 in the Y-direction. In other words, the width of the recesses may be selected to result in a desired width of the word line structures 122 (i.e., gate electrodes) formed from the gate electrode material in the Y-direction.

The x-axis trenches 118, including the first recesses between the word line structures 122 within the wide x-axis trenches 119, may be filled with a first insulative material 124. The first insulative material 124 may be a spin-on dielectric material, and may be formed by a spin coating process. Moreover, the first insulative material 124 may include any of the dielectric materials described herein. The first insulative material 124 may optionally be subjected to an annealing process.

Referring still to FIG. 1B, any of the first dielectric liner material 113, the second dielectric liner material 123, and the first insulative material 124 above an upper vertical boundary of the second doped region 112 of the semiconductor projections 108 may be removed. For example, any of the first dielectric liner material 113, the second dielectric liner material 123, and the first insulative material 124 above an upper vertical boundary of the second doped region 112 of the semiconductor projections 108 may be removed by way of a CMP process. In some embodiments, some of the second doped regions 112 of the semiconductor projections 108 may also be removed by way of the removal process. As a result, a distance between the word line structures 122 and an upper boundary of the second doped region 112 may be selected. Due to the removal of any of the first dielectric liner material 113, the second dielectric liner material 123, and the first insulative material 124 above an upper vertical boundary (or chosen upper vertical boundary) of the second doped regions 112 of the semiconductor projections 108, portions of the second doped region 112, the first dielectric liner material 113, the second dielectric liner material 123, and the first insulative material 124 are exposed on a current upper surface of the first assembly 104.

FIG. 1C is a simplified, vertical cross-sectional view of the first memory array structure 102 along the line A-A of FIG. 1B. Referring to FIG. 1B and FIG. 1C together, merged word line structures 122 within the thin x-axis trenches 120 may form a shield gate 125 or back gate that shields word line structures 122 from cross-interference between word line structures 122 within the wide x-axis trenches 119. For example, the shield gates 125 may control electrical field interference between vertical access devices 126 (e.g., vertical transistors, access transistors) (described below) that include the semiconductor projections 108. In some embodiments, the shield gates 125 are formed from tungsten or another conductive material. In one or more embodiments, the shield gates 125 are formed from a semiconductor material (e.g., polysilicon). Furthermore, the shield gates 125 may be operably connected to a respective voltage supply at an edge of the array.

Referring still to FIG. 1B and FIG. 1C together, an individual vertical access device 126 may include a channel region comprising the undoped region 111 of an individual semiconductor projection 108 (i.e., pillar), a drain region comprising the first doped region 110 of the semiconductor projection 108 (i.e., pillar), and a source region comprising the second doped region 112 of the semiconductor projection 108 (i.e., pillar). In addition, the vertical access devices 126 may include a gate electrode (e.g., a word line structure 122) and a gate dielectric material (e.g., the second dielectric liner material 123). A given word line structure 122 may be utilized as a gate electrode for multiple vertical access devices 126.

Referring to FIG. 1B and FIG. 1D together, a redistribution layer tier 127 (RDL tier 127) including redistribution structures 128 (RDM structures 128) and a first dielectric material 129 may be formed over the exposed surfaces of second doped regions 112 of the semiconductor projections 108, the first dielectric liner material 113, the second dielectric liner material 123, the first isolation material 117, and the first insulative material 124 of both of the first memory array structure 102 and the second memory array structure 103 of the first assembly 104 and over and across the edge of array region 107 of the microelectronic device 100. The RDM structures 128 may, for example, facilitate a horizontal arrangement (e.g., a hexagonal close packed arrangement) of storage node devices (e.g., capacitors) (described below) that is different than a horizontal arrangement of the contact structures of the semiconductor projections 108 of the first memory array structure 102 and the second memory array structure 103, while still electrically connecting the semiconductor projections 108 to the storage node devices. The RDM structures 128 may vertically overlie the first memory array structure 102 and the second memory array structure 103. The RDM structures 128 may be formed of and include one or more of W, Ru, Mo, and TiN_{y}.

A first multi-storage node structure 130 and a second multi-storage node structure 131, each including multiple storage node devices 132 (e.g., capacitors), may be formed on or over the RDL tier 127 and the RDM structures 128 to form a second assembly 133, the second assembly 133 including the first assembly 104, the first multi-storage node structure 130, and the second multi-storage node structure 131. The first multi-storage node structure 130 may be formed vertically over the first memory array structure 102, and the second multi-storage node structure 131 may be formed vertically over the second memory array structure 103. The storage node devices 132 may be in electrical contact with the RDM structures 128, and, hence, with the semiconductor projections 108 (e.g., the access devices 126 (FIG. 1C)). The storage node devices 132 may be coupled to the semiconductor projections 108 by way of the RDM structures 128 to form memory cells 134 (e.g., DRAM cells).

Each memory cell 134 may individually include one of the access devices 126 (FIG. 1C), one of the storage node devices 132, and one of the RDM structures 128. The storage node devices 132 may individually be formed and configured to store a charge representative of a programmable logic state of the memory cell 134 including the storage node device 132.

Referring to FIG. 1D and FIG. 1E together, in some embodiments, the storage node devices 132 include capacitors. During use and operation, a charged capacitor may represent a first logic state, such as a logic 1; and an uncharged capacitor may represent a second logic state, such as a logic 0. Each of the storage node devices 132 may, for example, be formed to include a first electrode 135 (e.g., a bottom electrode), a second electrode 136 (e.g., a top electrode), and a second dielectric material 137 between the first electrode 135 and the second electrode 136. For instance, each of the storage node devices 132 may include a metal-insulator-metal (MIM) capacitor. As another example, each of the storage node devices 132 may include a metal-insulator-semiconductor (MIS) capacitor. The collection of memory cells 134 may form a memory array.

The first multi-storage node structure 130 may further include a conductive material 138 formed between neighboring storage node devices 132. The conductive material 138 may substantially cover and surround the storage node devices 132. The second electrode 136 of the storage node devices 132 may be operatively positioned (e.g., embedded) within the conductive material 138. The conductive material 138 may include any of the conductive materials described herein. For instance, the conductive material 138 may include polysilicon or conductively-doped silicon germanium (SiGe).

A first cell plate 139 may be formed on and over the first multi-storage node structure 130 of the second assembly 133, and a second cell plate 140 may be formed on and over the second multi-storage node structure 131 of the second assembly 133. For instance, the first cell plate 139 may be formed on and over an upper surface of the conductive material 138 of the first multi-storage node structure 130, and the second cell plate 140 may be formed on and over an upper surface of the conductive material 138 of the second multi-storage node structure 131. Each of the first cell plate 139 and the second cell plate 140 may include any of the conductive materials described herein. For instance, one or more of the first cell plate 139 or the second cell plate 140 may include a tungsten (W).

In some embodiments, each of the first cell plate 139 and the second cell plate 140 are formed by way of a single deposition of a conductive material, and subsequently, the first cell plate 139 and the second cell plate 140 can be separated and defined by way of a chop etch within the edge of array region 107 of the second assembly 133. In some embodiments, the chop etch and separating the first cell plate 139 from the second cell plate 140 may be done by conventional techniques, such as by a directional, selective etch process (e.g., an anisotropic etch process, such as an anisotropic dry or wet etch process) that removes the conductive material forming the first cell plate 139 and the second cell plate 140 and the conductive material 138, the second electrode 136, and the second dielectric material 137 of the first multi-storage node structure 130 and second multi-storage node structure 131 within the edge of array region 107 of the second assembly 133 without significantly removing other exposed materials (e.g., the first dielectric material 129) of the RDL tier 127.

Referring still to FIG. 1D and FIG. 1E, each of the first cell plate 139 and the second cell plate 140 may include a respective contact portion 141, 142 formed within horizontal boundaries of the edge of array region 107 of the microelectronic device 100. In particular, each of the first cell plate 139 and the second cell plate 140 may extend horizontally in the X-direction into the edge of array region 107 of the microelectronic device 100 and may terminate within the edge of array region 107 of the microelectronic device 100. Put another way, each of the first cell plate 139 and the second cell plate 140 may have a horizontal boundary within the edge of array region 107 of the microelectronic device 100. Additionally, the conductive material 138, the second dielectric material 137, the first electrode 135, and the second electrode 136 of each of the first multi-storage node structure 130 and the second multi-storage node structure 131 may extend horizontally in the X-direction into the edge of array region 107 of the microelectronic device 100. Furthermore, each of the conductive material 138, the second dielectric material 137, the first electrode 135, and the second electrode 136 of each of the first multi-storage node structure 130 and the second multi-storage node structure 131 may share a horizontal boundary with a respective cell plate of the first cell plate 139 and the second cell plate 140 within the edge of array region 107 of the microelectronic device 100.

Additionally, a second insulative material 143 may be formed on and over exposed surfaces of the first cell plate 139, the second cell plate 140, and the conductive material 138, the second electrode 136, and the second dielectric material 137 of the first multi-storage node structure 130 and second multi-storage node structure 131. In some embodiments, the second insulative material 143 is formed of and includes a dielectric oxide material, such as SiOₓ (e.g., SiO₂). The second insulative material 143 may be substantially homogeneous, or the second insulative material 143 may be heterogeneous. Furthermore, in some embodiments, a third insulative material 144 may be formed on and over the second insulative material 143. For instance, the third insulative material 144 may be formed on and over an upper surface of the second insulative material 143. In some embodiments, the third insulative material 144 is formed of and includes a dielectric oxide material, such as SiOₓ (e.g., SiO₂). The third insulative material 144 may be substantially homogeneous, or the third insulative material 144 may be heterogeneous. In one or more embodiments, the third insulative material 144 is formed of a same material as the second insulative material 143. Furthermore, in some embodiments, the third insulative material 144 is not formed and is not included in the process of forming the microelectronic device 100. As is discussed in greater detail below, in some embodiments, one or more of the second insulative material 143 or the third insulative material 144 may be utilized to bond the second assembly 133 to another structure (e.g., a carrier structure, a diffusion structure) through dielectric-to-dielectric bonding, such as an oxide-to-oxide bonding.

Referring still to FIG. 1D and FIG. 1E, each of the first cell plate 139 and the second cell plate 140 may form an electrode of a common cell multi-capacitor structure (e.g., common structure of metal-insulator-metal (MIM) capacitors, common structure of metal-insulator-semiconductor (MIS) capacitors). In one or more embodiments, each of the first cell plate 139 and the second cell plate 140 and an associated cell capacitor structure are utilized to regulate voltages supplied to one or more of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. For instance, each of the first cell plate 139 and the second cell plate 140 may support and/or form a portion of so called “decoupling capacitors” and/or “pump capacitors.”

Referring now to FIG. 1D and FIG. 1F together, a carrier structure 145 (e.g., a shared carrier structure) may be formed to be attached to the second assembly 133 on a side of the second assembly 133 neighboring the first multi-storage node structure 130 and the second multi-storage node structure 131 of the second assembly 133. The carrier structure 145 may include a second base structure 146 and a diffusion structure 147 on and overlying the second base structure 146.

The diffusion structure 147 may include a first doped region 148 of a semiconductor material 149 and a second doped region 150 of the semiconductor material 149. Within the semiconductor material 149, save for an upper surface 151 of the first doped region 148, the first doped region 148 may be at least substantially surrounded the second doped region 150. In particular, within the XZ plane, the first doped region 148 may be surrounded on three consecutive sides by the second doped region 150 of the semiconductor material 149. Put another way, the first doped region 148 of the semiconductor material 149 may be partially embedded within the second doped region 150 of the semiconductor material 149. In some embodiments, the upper surface 151 of the first doped region 148 is at least substantially coplanar with an upper surface 152 of the second doped region 150.

In some embodiments, one of the first doped region 148 and the second doped region 150 is N-type doped, such as N-type doped to an N-type dopant concentration within a range of from about 10¹⁵ cm⁻³ to about 10²⁰ cm⁻³, while the other of the first doped region 148 and the second doped region 150 is P-type doped, such as P-type doped to a P-type dopant concentration within a range of from about −10¹³ cm⁻³ to about −10¹⁸ cm⁻³. In additional embodiments, one or more of the first doped region 148 and the second doped region 150 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor material 149 of the second base structure 146. A P-type dopant may include one or more of boron, aluminum, and gallium; and an N-type dopant may include one or more of arsenic, phosphorous, antimony, and bismuth. In view of the foregoing, because the first doped region 148 is doped with one of an N-dopant or a P-dopant, and the second doped region 150 is doped with the other of an N-dopant or a P-dopant, the first doped region 148 and the second doped region 150 form a PN junction which allows current to flow in one direction but not the other direction.

The diffusion structure 147 mitigates a risk of unintentional electrostatic discharge within the microelectronic device 100. For example, as is described in greater detail below, the diffusion structure 147 may be operably coupled to one or more devices and structures of the microelectronic device 100 and may provide a one-way pathway for discharging static electricity that builds up in the microelectronic device 100 during operation. For example, due to the PN junction formed by the diffusion structure 147, which permits current to flow in a single direction, the diffusion structure 147 may act as an antenna and a release of static electricity that builds up within the microelectronic device. In particular, the diffusion structure 147 may attract and collect electrostatic charge that builds up within the microelectronic device 100, and the PN junction provides a one-way controlled path for a discharge. In other words, the diffusion structure 147 provides a path for the static electricity to safely dissipate without damaging the microelectronic device 100. Accordingly, the diffusion structure 147 described herein can mitigate the risks of gate oxide breakdown, damage to p-n junctions, data corruption, latch-up conditions, functional interruptions, and leakage currents often associated with electrostatic discharge. As a result, the diffusion structure 147 described herein can improve reliability of microelectronic devices in comparison to conventional devices.

The second base structure 146 may include a base material or construction upon which additional features (e.g., materials, structures, devices) of the formed. In some embodiments, the second base structure 146 comprises a wafer. The second base structure 146 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the second base structure 146 may comprise a semiconductor wafer (e.g., a silicon wafer), a glass wafer, or a ceramic wafer. The second base structure 146 may include one or more layers, structures, and/or regions formed therein and/or thereon.

Referring to FIG. 1G, a fourth insulative material 153 may be formed on and over the upper surface 151 (FIG. 1F) of the first doped region 148 and the upper surface 152 (FIG. 1F) of the second doped region 150. In some embodiments, the fourth insulative material 153 is formed of and includes a dielectric oxide material, such as SiOₓ (e.g., SiO₂). The fourth insulative material 153 may be substantially homogeneous, or the fourth insulative material 153 may be heterogeneous. As is discussed below, the fourth insulative material 153 may be utilized to bond the carrier structure 145 to the second assembly 133 through dielectric-to-dielectric bonding, such as an oxide-to-oxide bonding.

In particular, to attach the carrier structure 145 to the second assembly 133 on a side of the second assembly 133 neighboring the first multi-storage node structure 130 and the second multi-storage node structure 131 of the second assembly 133, the fourth insulative material 153 of the carrier structure 145 may be provided in physical contact with at least the third insulative material 144 of the second assembly 133, and the fourth insulative material 153 of the carrier structure 145 and the third insulative material 144 of the second assembly 133 may be exposed to annealing conditions to form bonds (e.g., oxide-to-oxide bonds) between the fourth insulative material 153 and the third insulative material 144. By way of non-limiting example, the fourth insulative material 153 and the third insulative material 144 may be exposed to a temperature greater than or equal to about 400° C. (e.g., within a range of from about 300° C. to about 500° C., greater than about 500° C.) to form oxide-to-oxide bonds between the fourth insulative material 153 and the third insulative material 144. In some embodiments, the fourth insulative material 153 and the third insulative material 144 are exposed to at least one temperature greater than about 800° C. to form oxide-to-oxide bonds between the fourth insulative material 153 and the third insulative material 144.

Referring now to FIG. 1H and FIG. 1I together, the second assembly 133 may be vertically inverted such that the access devices 126 of the first memory array structure 102 and the second memory array structure 103 vertically overlay the first multi-storage node structure 130 and the second multi-storage node structure 131, and then at least one thinning process (e.g., a CMP process; an etching process, such as a conventional dry etching process or a wet etching process) may be performed on the first base structure 105 and the insulative structure 106 of the first assembly 104 to remove the first base structure 105 and the insulative structure 106. Furthermore, the thinning process may be stopped at upper surfaces (following vertical inversion) of the first dielectric liner material 113 and the first doped regions 110 of the semiconductor projections 108. For instance, the thinning process (e.g., the removal process) may be stopped at an intended digit line junction.

Referring to FIG. 1J, digit line structures 154 (e.g., bit line structures, data line structures) may be formed on or over the semiconductor projections 108 of the first memory array structure 102 and the second memory array structure 103 of the first assembly 104. In particular, the digit line structures 154 are formed vertically on or over each of the semiconductor projections 108 of the first memory array structure 102 and the second memory array structure 103 of the first assembly 104. The digit line structures 154 may be formed of and include a conductive material. The conductive material may include one or more conductive materials. In some embodiments, the conductive material includes tungsten, either alone or in combination with one or more conductive barrier materials (e.g., oxidation-resistant materials which protect the tungsten from oxidation in embodiments in which the tungsten may be exposed to oxygen).

The digit line structures 154 may be formed to any suitable dimensions (e.g., width, thickness). By way of example, the digit line structures 154 may individually be formed to a width, in the X-direction, equal to about the width of an individual semiconductor projection 108 (e.g., in a range of from about 10 nm to about 30 nm). The digit line structures 154 may be formed to any suitable pitch. The digit line structures 154 may be spaced apart from one another by a distance equal to about the distance between the semiconductor projections 108 horizontally neighboring one another in the X-direction.

The digit line structures 154 may be formed using any suitable processing. For instance, the conductive material may be formed on or over the upper surface of the second assembly 133 (e.g., upper surfaces of the first dielectric liner material 113 and the first doped regions 110 of the semiconductor projections 108), and a first mask material 155 may be formed over an upper surface of the conductive material, and the first mask material 155 may be patterned to form patterned masking lines horizontally extending in parallel with one another in the Y-direction. The first mask material 155 may be patterned into the patterned masking lines utilizing any suitable methodology. For instance, in some embodiments, a photoresist material is formed on or over the first mask material 155, is patterned (e.g., photo exposed and developed), and then openings formed in the patterned photoresist material are extended into the first mask material 155 to form the patterned masking lines.

The patterned masking lines may be employed to form additional y-axis trenches extending vertically through the conductive material formed over the first memory array structure 102 and the second memory array structure 103. The additional y-axis trenches may extend horizontally in parallel in the Y-direction. The additional y-axis trenches may have any suitable dimensions. For instance, the additional y-axis trenches may have a width, in the X-direction, at least substantially equal to about the width of an individual space between neighboring semiconductor projections 108. In some embodiments, the additional y-axis trenches are formed using an etching process (e.g., an anisotropic etching process) that selectively removes exposed portions of the conductive material relative to the patterned masking lines without removing portions of the first dielectric liner material 113. Accordingly, lower boundaries (e.g., bottoms) of the additional y-axis trenches, as defined by upper surfaces of the first dielectric liner material 113, may be substantially planar.

A third dielectric liner material 156 may be formed within the additional y-axis trenches, over the digit line structures 154 and the first mask material 155 of each of the first memory array structure 102 and the second memory array structure 103, and over the first dielectric liner material 113 within the edge of array region 107 between the first memory array structure 102 and the second memory array structure 103. For instance, the third dielectric liner material 156 may be formed (e.g., conformally deposited) inside the additional y-axis trenches, over the digit line structures 154 and first mask material 155, and over the first dielectric liner material 113 within the edge of array region 107 between the first memory array structure 102 and the second memory array structure 103. In some embodiments, the third dielectric liner material 156 may not entirely fill the additional y-axis trenches. For instance, recesses 157 may remain between portions of the third dielectric liner material 156 deposited on the sidewalls of the digit line structures 154 and the first mask material 155 of both of the first memory array structure 102 and the second memory array structure 103.

Within the additional y-axis trenches, the third dielectric liner material 156 may include side portions on the side surfaces of the digit line structures 154 and the first mask material 155, and, optionally, bottom portions on or over the upper surfaces of the first dielectric liner material 113.

The third dielectric liner material 156 may be formed of and include insulative material. In some embodiments, the third dielectric liner material 156 is formed of and includes silicon dioxide. The third dielectric liner material 156 may have a thickness within a range of from about 3 nm to about 7 nm (e.g., about 5 nm).

Referring still to FIG. 1J, a shield structure 158 may be formed over the third dielectric liner material 156. For instance, the shield structure 158 may be deposited (e.g., conformally deposited) within the recesses 157 and over the third dielectric liner material 156. The shield structure 158 may at least substantially entirely fill the recesses 157 and cover an upper surface of the third dielectric liner material 156. As a result, in some embodiments, the shield structure 158 includes projections 159 extending vertically downward between horizontally neighboring digit line structures 154. Moreover, because the shield structure 158 at least substantially entirely fills the recesses 157, the shield structure 158 may extend vertically in-between neighboring digit line structures 154. Put another way, portions of the shield structure 158 may be horizontally interposed between neighboring digit line structures 154 of the first memory array structure 102 and horizontally interposed between neighboring digit line structures 154 of the second memory array structure 103.

The shield structure 158 (e.g., upper shielding plate, top shielding plate) may be configured and positioned to shield (e.g., protect) features (e.g., structures, materials, devices, digit lines) within the memory cells 134 of the first memory array structure 102 and the second memory array structure 103 from undesirable electrical interference (e.g., electromagnetic interference (EMI)).

In some embodiments, the third dielectric liner material 156 at least substantially fills the additional y-axis trenches, and the shield structure 158 is formed over a substantially uniform or continuous upper surface of the third dielectric liner material 156. As a result, in some embodiments, the shield structure 158 does not include the projections 159 extending vertically downward between horizontally neighboring digit line structures 154 and, rather, may include a generally flat structure.

In view of the foregoing, the shield structure 158 may vertically overlie the digit line structures 154, which vertically overlie the access devices 126 of the memory cells 134 of each of the first memory array structure 102 and the second memory array structure 103. Accordingly, the access devices 126 of each of the first memory array structure 102 and the second memory array structure 103 may, respectively, be vertically interposed between the digit line structures 154 and the first multi-storage node structure 130 and the second multi-storage node structure 131.

The shield structure 158 may be formed of and include conductive material. In some embodiments, the shield structure 158 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 158 may be formed of and include tungsten (W). The shield structure 158 may be substantially homogeneous, or the shield structure 158 may be heterogeneous. If the shield structure 158 is heterogeneous, amounts of one or more elements included in the shield structure 158 may vary stepwise (e.g., change abruptly), or may vary continuously (e.g., change progressively, such as linearly, parabolically) throughout different portions of the shield structure 158. The shield structure 158 may, for example, be formed of and include a stack of at least two different conductive materials.

A fifth insulative material 160 may be formed over and on the shield structure 158 of the second assembly 133. In some embodiments, the fifth insulative material 160 is formed (e.g., deposited) through any of the manners described herein. Furthermore, the fifth insulative material 160 may be formed to have an at least substantially planar upper surface 161. In one or more embodiments, the fifth insulative material 160 is formed of and includes a dielectric oxide material, such as SiOₓ (e.g., SiO₂). The fifth insulative material 160 may be substantially homogeneous, or the fifth insulative material 160 may be heterogeneous. As is discussed in greater detail below, in some embodiments, the fifth insulative material 160 may be utilized to bond the second assembly 133 and, as a result, the first memory array structure 102 and the second memory array structure 103 to another structure (e.g., a second microelectronic device structure) through dielectric-to-dielectric bonding, such as an oxide-to-oxide bonding.

Referring to FIG. 1K, a second mask material 162 may be formed over the fifth insulative material 160, and the second mask material 162 may be patterned to form an opening 163 over the edge of array region 107 of the microelectronic device 100. The second mask material 162 may be patterned into the opening 163 utilizing any suitable methodology. For instance, in some embodiments, a photoresist material is formed on or over the second mask material 162, is patterned (e.g., photoexposed and developed), and then an opening formed in the patterned photoresist material are extended into the second mask material 162 to form the opening 163. Remaining portions of the second mask material 162 may be removed during subsequent processing stages, or may remain in a final device formed through the methods of the disclosure. The second mask material 162 may be formed of and include a dielectric material, such as a dielectric nitride material (e.g., silicide nitride).

The opening 163 within the second mask material 162 may be employed to form a chop trench 164 extending vertically into the second assembly 133 and through a portion of the fifth insulative material 160, a portion of the shield structure 158, a portion of the third dielectric liner material 156, and a portion of the first dielectric liner material 113 within the edge of array region 107 of the microelectronic device 100. Formation of the chop trench 164 may remove a portion of the shield structure 158 formed within the edge of array region 107 of the microelectronic device 100 and separate a portion of the shield structure 158 over the first memory array structure 102 of the microelectronic device 100 from a portion of the shield structure 158 over the second memory array structure 103 of the microelectronic device 100. Removing the portion of the shield structure 158 formed within the edge of array region 107 of the microelectronic device 100 may define a first shield structure 165 over the first memory array structure 102 of the microelectronic device 100 and a second shield structure 166 over the second memory array structure 103 of the microelectronic device 100.

In one or more embodiments, the chop trench 164 is formed using an etching process (e.g., an anisotropic etching process) that selectively removes exposed portions of the fifth insulative material 160, the portion of the shield structure 158, the portion of the third dielectric liner material 156, and the portion of the first dielectric liner material 113 relative to the second first mask material 162 without removing portions of the first isolation material 117. Accordingly, lower boundaries (e.g., bottoms) of the chop trench 164, as defined by an upper surface of the first isolation material 117, may be substantially planar.

Referring to FIG. 1K and FIG. 1L together, the second mask material 162 above a vertical boundary of the fifth insulative material 160 may be removed. For example, the second mask material 162 may be removed by way of a CMP process. Additionally, the chop trench 164 may be filled with a sixth insulative material 167. The sixth insulative material 167 may be a spin-on dielectric material and may be formed by a spin coating process. Moreover, the sixth insulative material 167 may include any of the dielectric materials described herein. For instance, the sixth insulative material 167 may include a same dielectric material as the fifth insulative material 160. The sixth insulative material 167 may optionally be subjected to an annealing process. In some embodiments, the sixth insulative material 167 and the fifth insulative material 160 are subjected to a planarization process such that upper surfaces of the sixth insulative material 167 and the fifth insulative material 160 are at least substantially planar and coplanar.

Referring next to FIG. 1M, a third mask material 168 may be formed over the fifth insulative material 160 and the sixth insulative material 167, and the third mask material 168 may be patterned to form first y-axis openings 169. The first y-axis openings 169 may extend horizontally in parallel in the Y-direction (e.g., a first direction). The first y-axis openings 169 may have any suitable dimensions. The first y-axis openings 169 may include a central first y-axis opening 170 and two lateral first y-axis openings 171 on opposing lateral sides of the central first y-axis opening 170 in the X-direction. In some embodiments, the central first y-axis opening 170 horizontally overlaps (e.g., is horizontally aligned) and is directly vertically above the first doped region 148 of the carrier structure 145, and each of the other two lateral first y-axis openings 171 horizontally overlaps and is directly vertically above a respective contact portion 141, 142 of either the first cell plate 139 or the second cell plate 140 within the edge of array region 107 of the microelectronic device 100. The first y-axis openings 169 may extend horizontally in parallel in the Y-direction (e.g., a first direction).” The first y-axis openings 169 may have any suitable dimensions.

The third mask material 168 may be patterned to form the form first y-axis openings 169 utilizing any suitable methodology. For instance, in some embodiments, a photoresist material is formed on or over the third mask material 168, is patterned (e.g., photoexposed and developed), and then openings formed in the patterned photoresist material are extended into the third mask material 168 to form the form the first y-axis openings 169. The third mask material 168 may be removed during subsequent processing stages, or may remain in a final device formed through the methods of the disclosure. The third mask material 168 may be formed of and include a dielectric material, such as a dielectric nitride material (e.g., silicide nitride).

The central first y-axis opening 170 may be employed to form a central first y-axis trench 172 extending vertically into the second assembly 133 and to the first doped region 148 of the carrier structure 145. According, the upper surface 151 of the first doped region 148 may be exposed by the central first y-axis trench 172. The two lateral first y-axis openings 171 may be employed to form two lateral first y-axis trenches 173 extending vertically into the second assembly 133 and to at least the second electrodes 136 of the first multi-storage node structure 130 and the second multi-storage node structure 131 vertically above the contact portions 141, contact portions 142 of the first cell plate 139 and the second cell plate 140. Accordingly, upper surfaces of the second electrodes 136 may be exposed by the two lateral first y-axis trenches 173. In additional embodiments, the two lateral first y-axis openings 171 also extend through one or more of the second electrode 136 and the conductive material 138 of the first multi-storage node structure 130 or the second multi-storage node structure 131, respectively. For example, each the two lateral first y-axis trenches 173 may extend vertically to a respective contact portion 141, 142 of the first cell plate 139 and the second cell plate 140. In such embodiments, the contact portions 141, 142 of the first cell plate 139 and the second cell plate 140 may be exposed by the two lateral first y-axis trenches 173.

In some embodiments, the central first y-axis opening 170 and the two lateral first y-axis trenches 173 are formed using one or more etching processes (e.g., anisotropic etching processes) that selectively removes exposed portions of the sixth insulative material 167, the first isolation material 117, first dielectric material 129, the second dielectric material 137, the second insulative material 143, the third insulative material 144, and the fourth insulative material 153 without removing portions of the second electrode 136 or the first doped region 148.

Referring to FIG. 1M and FIG. 1N, the third mask material 168 may be removed by way of a CMP process or any other removal process described herein. Additionally, a second conductive material 174 may be formed within the central first y-axis trench 172, within the two lateral first y-axis trenches 173, and on and over upper surfaces of the fifth insulative material 160 and the sixth insulative material 167. For instance, the central first y-axis trench 172 and the two lateral first y-axis trenches 173 may be filled with the second conductive material 174. In some embodiments, the second conductive material 174 is formed of any of the conductive materials described herein. For example, the second conductive material 174 may be formed of and include one or more of W, Cu, Al, Ru, Mo, and TiN_{y}. The second conductive material 174 may be formed (e.g., deposited) via and of the manners described herein.

Forming the second conductive material 174 on and over the upper surfaces of the fifth insulative material 160 and the sixth insulative material 167 may form portions of a first routing tier 175 and be utilized to form later-formed first routing structures 182 (FIG. 1P). Additionally, filling the central first y-axis trench 172 with the second conductive material 174 may form a first interconnect structure 176 that extends vertically between and contacts (e.g., physically contacts, electrically contacts) the diffusion structure 147 and the first routing tier 175, and, as a result, the later-formed first routing structures 182 (FIG. 1P). Put another way, the first interconnect structure 176 may extend vertically from an elevation above upper boundaries of the access devices 126 of the first memory array structure 102 and the second memory array structure 103 to the first doped region 148 of the diffusion structure 147. Furthermore, filling the two lateral first y-axis trenches 173 with the second conductive material 174 may form second interconnect structures 177 that extend vertically between and contact (e.g., physically contact, electrically contact) a respective cell plate and the first routing tier 175, and, as a result, the later-formed first routing structures 182 (FIG. 1P).

As is described in greater detail below, the first interconnect structure 176 may be in contact with (e.g., physical contact, electrical contact) the diffusion structure 147 (e.g., the first doped region 148 of the diffusion structure 147) and may facilitate an electrical pathway between structures or devices operably connected to first routing structures 182 of the first routing tier 175 and the diffusion structure 147. For example, the first interconnect structure 176 may enable electrostatic charge that has built up within any structures or devices operably connected to first routing structures of the first routing tier 175 to be safely dissipated by way of the diffusion structure 147, as described above. Furthermore, the first interconnect structure 176 may be horizontally in between the first memory array structure 102 and the second memory array structure 103 in the X-direction and within the edge of array region 107 of the microelectronic device 100.

The second interconnect structures 177 may be in contact with (e.g., physical contact, electrical contact) a respective cell plate of the first cell plate 139 and the second cell plate 140 and may facilitate operable communication between structures or devices operably connected to first routing structures of the first routing tier 175 and the first cell plate 139 and the second cell plate 140.

In some embodiments, an upper surface of the second conductive material 174 on or over the upper surfaces of the fifth insulative material 160 and the sixth insulative material 167 is planarized by way of a metal CMP process, such as a CMP stop on dielectric process.

Referring next to FIG. 1O, a seventh insulative material 178 may be formed on and over the second conductive material 174. In some embodiments, the seventh insulative material 178 is formed (e.g., deposited) through any of the manners described herein. Furthermore, the seventh insulative material 178 may be formed to have an at least substantially planar upper surface. In one or more embodiments, the seventh insulative material 178 is formed of and includes a dielectric oxide material, such as SiOₓ (e.g., SiO₂). The seventh insulative material 178 may be substantially homogeneous, or the seventh insulative material 178 may be heterogeneous.

Additionally, a fourth mask material 179 may be formed on and over the seventh insulative material 178, and the fourth mask material 179 may be patterned to form second y-axis openings 180 and first x-axis openings 181. The second y-axis openings 180 may be formed within the edge of array region 107 of the microelectronic device 100 and may extend horizontally in parallel in the Y-direction (e.g., a first direction). The second y-axis openings 180 may have any suitable dimensions. In some embodiments, each of the second y-axis openings 180 horizontally overlaps and is directly vertically above a respective region of the microelectronic device 100 horizontally offset from the first interconnect structure 176 and the second interconnect structures 177 in the X-direction. For example, a first of the second y-axis openings 180 may horizontally overlap with a region in-between the first interconnect structure 176 and a first of the second interconnect structure 177 in the X-direction, and a second of the second y-axis openings 180 may horizontally overlap with a region in-between the first interconnect structure 176 and a second of the second interconnect structure 177 in the X-direction. Likewise, a third of the second y-axis openings 180 may horizontally overlap with a region on a lateral side of the first of the second interconnect structure 177 opposite the first interconnect structure 176, and a fourth of the second y-axis openings 180 may horizontally overlap with a region on a lateral side of the second of the second interconnect structure 177 opposite the first interconnect structure 176. As is discussed in greater detail below, the second y-axis openings 180 may be utilized to define first routing structures 182 (FIG. 1P) within the first routing tier 175 from the second conductive material 174 and to separate a first routing structure 182 (FIG. 1P) operably coupled to the first interconnect structure 176 from first routing structures 182 (FIG. 1P) operably coupled to the second interconnect structures 177.

The first x-axis openings 181 may be formed within a first set vertically above and horizontally overlapping the first memory array structure 102 and a second set vertically above and horizontally overlapping the second memory array structure 103. Within each of the first set and the second set, the first x-axis openings 181 may extend horizontally in parallel in the X-direction (e.g., a second direction). As is discussed in greater detail below, the first x-axis openings 181 may be utilized to define first routing structures 182 (FIG. 1P) within the first routing tier 175 from the second conductive material 174 and to separate first routing structures 182 (FIG. 1P) from each other in the Y-direction.

The fourth mask material 179 may be patterned to form the second y-axis openings 180 and the first x-axis openings 181 utilizing any suitable methodology. For instance, in some embodiments, a photoresist material is formed on or over the fourth mask material 179, is patterned (e.g., photoexposed and developed), and then openings formed in the patterned photoresist material are extended into the fourth mask material 179 to form the form the second y-axis openings 180 and the first x-axis openings 181. The fourth mask material 179 may be formed of and include a dielectric material, such as a dielectric nitride material (e.g., silicide nitride).

Referring next to FIG. 1O and FIG. 1P together, the second y-axis openings 180 and the first x-axis openings 181 may be employed to pattern the second conductive material 174 over the fifth insulative material 160 and the sixth insulative material 167 and to form first routing structures 182 from the second conductive material 174. In particular, the second y-axis openings 180 and the first x-axis openings 181 may be employed to form trenches extending through the seventh insulative material 178 and the second conductive material 174. Furthermore, the trenches may be formed to extend from an upper surface of the seventh insulative material 178 to an elevation at or below the planar upper surface 161 (FIG. 1J) of the fifth insulative material 160 and the sixth insulative material 167.

Additionally, the fourth mask material 179 may be removed by way of a CMP process or any other removal process described herein. An eighth insulative material 183 may be formed within the trenches extending through the seventh insulative material 178 and the second conductive material 174 and, optionally, on and over upper surfaces of the seventh insulative material 178. For instance, the trenches may be filled with the eighth insulative material 183. Moreover, the eighth insulative material 183 may include any of the dielectric materials described herein. In some embodiments, the eighth insulative material 183 is formed of and includes a dielectric oxide material, such as SiOₓ (e.g., SiO₂). In one or more embodiments, the eighth insulative material 183 is a spin-on dielectric material, and may be formed by a spin coating process. The eighth insulative material 183 may be substantially homogeneous, or the eighth insulative material 183 may be heterogeneous. Furthermore, the eighth insulative material 183 may be formed to have an at least substantially planar upper surface. The eighth insulative material 183 may be formed (e.g., deposited) via and of the manners described herein.

Referring to FIG. 1Q, a fifth mask material 184 may be formed on and over the eighth insulative material 183, and the fifth mask material 184 may be patterned to form interconnect openings 185. The interconnect openings 185 may be formed vertically above and horizontally overlapping the first memory array structure 102 and the second memory array structure 103. For example, each interconnect opening 185 may horizontally overlap with one of the first routing structures 182 vertically overlying one of the first memory array structure 102 or the second memory array structure 103. Furthermore, a width of any given interconnect opening 185 in the Y-direction may be at least substantially equal to a width of a respective first routing structure 182 in the Y-direction with which the given interconnect opening 185 horizontally overlaps. As is discussed in greater detail below in regard to FIG. 1R, the interconnect openings 185 may be utilized to form interconnect structures between the first routing tier 175 and a second routing tier 188 (FIG. 1R).

The fifth mask material 184 may be patterned to form the interconnect openings 185 utilizing any suitable methodology. For instance, in some embodiments, a photoresist material is formed on or over the fifth mask material 184, is patterned (e.g., photoexposed and developed), and then openings formed in the patterned photoresist material are extended into the fifth mask material 184 to form the form the interconnect openings 185. The fifth mask material 184 may be formed of and include a dielectric material, such as a dielectric nitride material (e.g., silicide nitride).

Referring to FIG. 1Q and FIG. 1R together, the interconnect openings 185 may be employed to pattern the eighth insulative material 183. In particular, the interconnect openings 185 may be employed to form first interconnect trenches 186 extending through the eighth insulative material 183. Furthermore, the first interconnect trenches 186 may be formed to extend from an upper surface of the eighth insulative material 183 to the second conductive material 174 of the first routing tier 175.

The fifth mask material 184 may be removed by way of a CMP process or any other removal process described herein. Additionally, a third conductive material 187 may be formed within the first interconnect trenches 186, and on and over upper surfaces of the eighth insulative material 183. For instance, the first interconnect trenches 186 may be filled with the third conductive material 187. In some embodiments, the third conductive material 187 is formed of any of the conductive materials described herein. For example, the third conductive material 187 may be formed of and include one or more of W, Cu, Al, Ru, Mo, and TiN_{y}. The third conductive material 187 may be formed (e.g., deposited) via and of the manners described herein.

Forming the third conductive material 187 on and over the upper surfaces of the eighth insulative material 183 may form portions of a second routing tier 188 and be utilized to form later-formed second routing structures 189. Additionally, filling the first interconnect trenches with the third conductive material 187 may form third interconnect structures 190 that extend vertically between the first routing structures 182 of the first routing tier 175 and the second routing structures 189 of the second routing tier 188. In particular, the third interconnect structures 190 may be formed vertically overlying the first routing structures 182. Some of the second routing structures 189 may be coupled to the third interconnect structures 190.

The individual third interconnect structures 190 may be formed to contact (e.g., physically contact, electrically contact) and extend vertically between the first routing structures 182 and the second routing structures 189. For example, the third interconnect structures 190 may be formed to couple at least one of the second routing structures 189 to at least some of the first routing structures 182. The second routing structures 189 may be formed and defined by way of any of the manners described above in regard to FIG. 1P through which the first routing structures 182 were formed and defined.

Referring still to FIG. 1Q and FIG. 1R together, the edge of array region 107 of the microelectronic device 100 may be free of second routing structures 189 and third interconnect structures 190. In particular, first interconnect trenches 186 may not be formed within the edge of array region 107 of the microelectronic device 100 and any third conductive material 187 may be removed when removing portions of the third conductive material 187 to define the second routing structures 189. As will be described in greater detail in regard to FIG. 2D, not forming second routing structures 189 and third interconnect structures 190 within the edge of array region 107 of the microelectronic device 100 enables a later-formed fifth interconnect structure 234 (FIG. 2B) to be formed vertically above and in contact with (e.g., physical contact, electrical contact) the first routing structure 182 contacting the first interconnect structure 176, which contacts the diffusion structure 147.

Additionally, a ninth insulative material 191 may be formed on and over exposed surfaces of the second routing structures 189 and the eighth insulative material 183. In some embodiments, the ninth insulative material 191 is formed of and includes a dielectric oxide material, such as SiOₓ (e.g., SiO₂). The ninth insulative material 191 may be substantially homogeneous, or the ninth insulative material 191 may be heterogeneous. Furthermore, in some embodiments, a tenth insulative material 192 may be formed on and over the ninth insulative material 191. For instance, the tenth insulative material 192 may be formed on and over an upper surface of the ninth insulative material 191. In some embodiments, the tenth insulative material 192 is formed of and includes a dielectric oxide material, such as SiOₓ (e.g., SiO₂). The tenth insulative material 192 may be substantially homogeneous, or the tenth insulative material 192 may be heterogeneous. In one or more embodiments, the tenth insulative material 192 is formed of a same material as the ninth insulative material 191. Furthermore, in some embodiments, the tenth insulative material 192 is not formed and is not included in the process of forming the microelectronic device. As is discussed in greater detail below, in some embodiments, one or more of the ninth insulative material 191 or the tenth insulative material 192 may be utilized to bond the second assembly 133 to another structure (e.g., a control circuitry structure) through dielectric-to-dielectric bonding, such as an oxide-to-oxide bonding.

Referring to FIG. 2A, a control circuitry structure 202 may be bonded to the second assembly 133, the first memory array structure 102, and the second memory array structure 103 through a dielectric-to-dielectric bond, such as an oxide-to-oxide bond.

The control circuitry structure 202 may include a third base structure 204 including a second semiconductor material 206 formed on or over the third base structure 204 and isolation structures 208 (e.g., shallow trench isolation (STI) structures) extending vertically at least partially through the second semiconductor material 206 of the control circuitry structure 202.

The second base structure 146 may include a base material or construction upon which additional features (e.g., materials, structures, devices) of the control circuitry structure 202 may be formed. The second base structure 146 may include a semiconductor structure (e.g., a semiconductor wafer), or a base semiconductor material on a supporting structure. For example, the second base structure 146 may include a conventional silicon substrate (e.g., a conventional silicon wafer), or another bulk substrate including a semiconductor material. In some embodiments, the second base structure 146 includes a silicon wafer. The second base structure 146 may include one or more other layers, structures, and/or regions formed therein and/or thereon. The second semiconductor material 206 may include any of the semiconductor materials described herein.

The isolation structures 208 may include trenches (e.g., openings, vias, apertures) within at least the second semiconductor material 206 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the further isolation structures 208 are respectively formed of and include SiOₓ (e.g., SiO₂).

As noted briefly above, the isolation structures 208 may, for example, be employed as STI structures within the third base structure 204. The isolation structures 208 may be formed to extend vertically partially (e.g., less than completely) through the second semiconductor material 206. In some embodiments, a vertical depth (e.g., vertical height) of the isolation structures 208 is within a range of from about 200 nanometers (nm) to about 2000 nm. Each of the isolation structures 208 may be formed to exhibit substantially the same dimensions and shape as each other of the isolation structures 208, or at least one of the isolation structures 208 may be formed to exhibit one or more of different dimensions and a different shape than at least one other of the isolation structures 208. As a non-limiting example, each of the isolation structures 208 may be formed to exhibit substantially the same vertical dimension(s) and substantially the same vertical cross-sectional shape(s) as each other of the isolation structures 208; or at least one of the isolation structures 208 may be formed to exhibit one or more of different vertical dimension(s) and different vertical cross-sectional shape(s) than at least one other of the isolation structures 208. In some embodiments, the isolation structures 208 are all formed to extend vertically to and terminate at substantially the same depth within the second semiconductor material 206. In additional embodiments, at least one of the isolation structures 208 is formed to extend vertically to and terminate at a relatively deeper depth within the second semiconductor material 206 than at least one other of the isolation structures 208. As another non-limiting example, each of the isolation structures 208 may be formed to exhibit substantially the same horizontal dimension(s) and substantially the same horizontal cross-sectional shape(s) as each other of the isolation structures 208; or at least one of the isolation structures 208 may be formed to exhibit one or more of different horizontal dimension(s) (e.g., relatively larger horizontal dimension(s), relatively smaller horizontal dimension(s)) and different horizontal cross-sectional shape(s) than at least one other of the isolation structures 208. In some embodiments, at least one of the isolation structures 208 is formed to have one or more different horizontal dimensions (e.g., in the X-direction and/or in the Y-direction) than at least one other of isolation structures 208.

The control circuitry structure 202 may further include transistors 210. The transistors 210 may individually include conductively doped regions (e.g., source/drain regions), a channel region, a gate structure (e.g., a gate electrode), and a gate dielectric material. For an individual transistor 210, the conductively doped regions thereof may be formed within the second semiconductor material 206 of the control circuitry structure 202; the channel region thereof may be formed within the second semiconductor material 206 of the control circuitry structure 202 and may be horizontally interposed between the conductively doped regions of the individual transistor 210; the gate structure may vertically overlie and horizontally overlap the channel region of the individual transistor 210; and the gate dielectric material (e.g., dielectric oxide material) may be vertically interposed (e.g., in the Z-direction) between the gate structure and the channel region.

For an individual transistor, the conductively doped regions thereof may include the second semiconductor material 206 of the control circuitry structure 202 doped with one or more desired conductivity-enhancing dopants. In some embodiments, the conductively doped regions of the transistor 210 includes the second semiconductor material 206 doped with at least one N-type dopant (e.g., one or more of phosphorus, arsenic, antimony, and bismuth). In some of such embodiments, the channel region of the transistor 210 includes the second semiconductor material 206 doped with at least one P-type dopant (e.g., one or more of boron, aluminum, and gallium). In some other of such embodiments, the channel region of the transistor 210 includes substantially undoped second semiconductor material 206. In additional embodiments, for an individual transistor 210, the conductively doped regions include the second semiconductor material 206 doped with at least one P-type dopant (e.g., one or more of boron, aluminum, and gallium). In some of such additional embodiments, the channel region of the transistor 210 includes the second semiconductor material 206 doped with at least one N-type dopant (e.g., one or more of phosphorus, arsenic, antimony, and bismuth). In some other of such additional embodiments, the channel region of the transistor 210 includes substantially undoped second semiconductor material 206.

The gate structures (e.g., gate electrodes, gates) may individually horizontally extend between and be employed by multiple transistors 210. The gate structures may be formed of and include conductive material. The gate structures may individually be substantially homogeneous, or the gate structures may individually be heterogeneous. In some embodiments, the gate structures are each substantially homogeneous. In additional embodiments, the gate structures are each heterogeneous. Individual gate structures may, for example, be formed of and include a stack of at least two different conductive materials.

The control circuitry structure 202 may further include a dielectric capping structures form on upper surfaces of the gate structures, and dielectric spacer structures on side surfaces of (e.g., horizontally bookending) the gate structures, the gate dielectric material, and the dielectric capping structures.

In addition, the control circuitry structure 202 further includes fourth interconnect structures 212 vertically overlying and in contact with (e.g., physical contact, electrical contact) the conductively doped regions of the transistors 210. In some embodiments, the fourth interconnect structures 212 vertically overlie, horizontally overlap, and physically contact the conductively doped regions of the transistors 210. The fourth interconnect structures 212 may individually be formed of and include conductive material. In some embodiments, the fourth interconnect structures 212 are individually formed of and include one or more of W, Ru, Mo, and TiN_{y}.

In some embodiments, the control circuitry structure 202 further includes a third routing tier 214 having third routing structures 216 vertically overlying the transistors 210. Some of the third routing structures 216 may be coupled to the fourth interconnect structures 212 (and, hence, the transistors 210). The third routing structures 216 may respectively be formed of and include conductive material. In some embodiments, the third routing structures 216 are individually formed of and include one or more of W, Ru, Mo, and TiN_{y}. As is discussed in greater detail in regard to FIG. 2D, the third routing structures may be further defined by later-formed trenches.

The transistors 210, the fourth interconnect structures 212, and at least some of the third routing structures 216 may form control logic circuitry of various control logic devices 218 configured to control various operations of various features (e.g., the memory cells 134) of the microelectronic device 100 (e.g., a memory device, such as a DRAM device). In some embodiments, the control logic devices 218 include complementary metal-oxide-semiconductor (CMOS) circuitry. As a non-limiting example, the control logic devices 218 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions of the control circuitry structure 202 may have different control logic devices 218 formed within horizontal areas thereof.

Referring still to FIG. 2A, the control circuitry structure 202 may include at least one isolation structure 208 horizontally overlapping with the edge of array region 107 of the microelectronic device 100. In some embodiments, the at least one isolation structure 208 is vertically above and horizontally overlaps with the first interconnect structure 176 that is in contact with the first doped region 148 of the diffusion structure 147 of the carrier structure 145. In particular, the at least one isolation structure 208 may be directly vertically above the first interconnect structure 176 that is in contact with the first doped region 148 of the diffusion structure 147. The control circuitry structure 202 may further include a trench 220 (e.g., opening, via, aperture) formed within the at least one isolation structure 208 of the second semiconductor material 206, the second semiconductor material 206 itself, and the third base structure 204. The at least one isolation structure 208, the second semiconductor material 206, and the third base structure 204 may at least substantially define lateral sidewalls of the trench 220. In other words, the trench 220 may be formed vertically through the at least one isolation structure 208 of the second semiconductor material, the second semiconductor material 206 itself, and the third base structure 204 such that the at least one isolation structure 208, the second semiconductor material 206, and the third base structure 204 define the lateral boundaries (i.e., lateral sidewalls) of the trench 220.

An eleventh insulative material 222 may be formed on or over portions of at least the third base structure 204, the transistors 210, the fourth interconnect structures 212, the control logic devices 218, and the third routing structures 216. The eleventh insulative material 222 may also be formed within the trench 220. In some embodiments, the eleventh insulative material 222 is formed of and includes a dielectric oxide material, such as SiOₓ (e.g., SiO₂). The eleventh insulative material 222 may be substantially homogeneous, or the eleventh insulative material 222 may be heterogeneous. An upper surface of the eleventh insulative material 222 may be formed to be substantially planar. In some embodiments, the upper surface of the eleventh insulative material 222 is formed to be substantially coplanar with lower surfaces of the third routing structures 216.

A twelfth insulative material 224 may be formed on or over portions of at least the eleventh insulative material 222 and the third routing structures 216. In some embodiments, the twelfth insulative material 224 is formed of and includes a dielectric oxide material, such as SiOₓ (e.g., SiO₂). The twelfth insulative material 224 may be substantially homogeneous, or the twelfth insulative material 224 may be heterogeneous. An upper surface of the twelfth insulative material 224 may be formed to be substantially planar. In some embodiments, the upper surface of the twelfth insulative material 224 is formed vertically overlie the upper surfaces of the third routing structures 216.

Referring still to FIG. 2A, as noted briefly above, the control circuitry structure 202 may be attached to the second assembly 133 by way of one or more bonds (e.g., oxide-to-oxide bonds). In particular, a thirteenth insulative material 226 of the control circuitry structure 202 underlying the third base structure 204 may be put in physical contact with the tenth insulative material 192 of the second assembly 133, and then the thirteenth insulative material 226 and the tenth insulative material 192 may be exposed to annealing conditions to form bonds (e.g., dielectric-to-dielectric bonds, such as oxide-to-oxide bonds) between the thirteenth insulative material 226 and the tenth insulative material 192. By way of non-limiting example, the thirteenth insulative material 226 and the tenth insulative material 192 may be exposed to a temperature greater than or equal to about 400° C. (e.g., within a range of from about 400° C. to about 800° C., greater than about 800° C.) to form bonds between the thirteenth insulative material 226 and the tenth insulative material 192. While FIG. 2A depicts a bond line representing an initial interface location between the second assembly 133 and the control circuitry structure 202 before the bonding process, the thirteenth insulative material 226 and the tenth insulative material 192 may be integral and continuous with one another following the bonding process. In particular, the control circuitry structure 202 may be attached to the second assembly 133 without a bond line.

In view of the foregoing, the control circuitry structure 202 may be attached to a side of the second assembly vertically closer to the access devices 126 of the memory cells 134 than the storage node devices 132 of the memory cells 134. Put another way, the control circuitry structure 202 may be attached to a side of the second assembly 133 (and the first memory array structure 102 and the second memory array structure 103) opposite the first multi-storage node structure 130 and the second multi-storage node structure 131. Furthermore, the shield structure 158 and digit line structures 154 may be vertically interposed between the control circuitry structure 202 and the memory cells 134, the access devices 126 may be vertically interposed between the first multi-storage node structure 130 and the second multi-storage node structure 131 and the control circuitry structure 202, and the access devices 126 may be vertically interposed between the first multi-storage node structure 130, the second multi-storage node structure 131, and the shield structure 158 and digit line structures 154.

Referring to FIG. 2A and FIG. 2B together, subsequent to attaching the control circuitry structure 202 to the second assembly 133, a deep trench 228 may be formed to expose a first routing structure 182 contacting the first interconnect structure 176. In particular, the deep trench 228 may be formed through the twelfth insulative material 224, the eleventh insulative material 222, the trench 220 within one of the isolation structures 208, the thirteenth insulative material 226, the tenth insulative material 192, the ninth insulative material 191, and the eighth insulative material 183 to a first routing structure 182 contacting the first interconnect structure 176. In some embodiments, the deep trench 228 is at least substantially horizontally aligned with trench 220 (FIG. 2A).

The deep trench 228 may be formed through any of the manners described herein. For example, the deep trench 228 may be formed utilizing a mask material and an etching process (e.g., an anisotropic etching process) that selectively removes exposed portions of the twelfth insulative material 224, the eleventh insulative material 222, the thirteenth insulative material 226, the tenth insulative material 192, the ninth insulative material 191, and the eighth insulative material 183 without removing portions of one or more of the isolation structure 208, the second semiconductor material 206, the third base structure 204, and the first routing structure 182. Accordingly, a lower boundary (e.g., bottom) of the deep trench 228, as defined by an upper surface of the first routing structure 182, may be substantially planar.

Following formation of the deep trench 228, a fourth conductive material 230 may be formed within the deep trench 228 and on and over upper surface of the twelfth insulative material 224. For instance, the deep trench 228 may be filled with the fourth conductive material 230. In some embodiments, the fourth conductive material 230 is formed of any of the conductive materials described herein. For example, the fourth conductive material 230 may be formed of and include one or more of W, Cu, Al, Ru, Mo, and TiN_{y}. The fourth conductive material 230 may be formed (e.g., deposited) via and of the manners described herein.

Forming the fourth conductive material 230 on and over the upper surface of the twelfth insulative material 224 may form portions of a fourth routing tier 232 and be utilized to form later-formed fourth routing structures 236 (FIG. 2D). Additionally, filling the deep trench 228 with the fourth conductive material 230 may form a fifth interconnect structure 234 (e.g., an electrostatic discharge interconnect structure) that extends vertically between the diffusion structure 147 and the fourth routing tier 232, and, as a result, at least one later-formed fourth routing structures 236 (FIG. 2D).

The fifth interconnect structure 234 is formed to contact (e.g., physically contact, electrically contact) the first routing structure 182 contacting (e.g., physically contacting, electrically contacting) the first interconnect structure 176, which is in contact with (e.g., in physical contact, electrical contact with) the diffusion structure 147 (e.g., the first doped region 148 of the diffusion structure 147) and may provide an electrical pathway between any of the devices (e.g., control logic devices 218 within the control circuitry structure 202) and the diffusion structure 147. For example, the fifth interconnect structure 234 may enable electrostatic charge that has built up within any structures or devices operably connected to first routing structures 182 of the first routing tier 175 and the fourth routing tier 232 to be safely dissipated by way of the diffusion structure 147.

As noted above, the diffusion structure 147 mitigates a risk of unintentional electrostatic discharge within the microelectronic device 100. For example, due to the PN junction formed by the diffusion structure 147, which permits current to flow in a single direction, the diffusion structure 147 may act as an antenna and a release of static electricity that builds up within the microelectronic device 100, such as the control logic devices 218 of the control circuitry structure 202. In particular, the diffusion structure 147 may attract and collect electrostatic charge that builds up within the microelectronic device 100 (e.g., any of the devices or structures operably coupled to the first routing structures 182 of the first routing tier 175 or the fourth routing structures 236 (FIG. 2D) of the fourth routing tier 232), and the PN junction provides a one-way controlled path for a discharge. In other words, the diffusion structure 147 provides a path for the static electricity to safely dissipate without damaging the microelectronic device 100. Accordingly, the diffusion structure 147 described herein can mitigate the risks of gate oxide breakdown, damage to p-n junctions, data corruption, latch-up conditions, functional interruptions, and leakage currents often associated with electrostatic discharge. As a result, the diffusion structure 147 described herein can improve reliability of microelectronic devices in comparison to conventional devices.

The fifth interconnect structure 234 may extend vertically from the fourth routing tier 232, through an isolation structure 208 of the second semiconductor material 206, and to the first routing structure 182 contacting the first interconnect structure 176. Accordingly, the fifth interconnect structure 234 vertically overlaps with at least a portion of the control circuitry structure 202, the first memory array structure 102, and the second memory array structure 103 of the microelectronic device 100.

In some embodiments, an upper surface of the fourth conductive material 230 on or over the upper surface of the twelfth insulative material 224 may be planarized by way of a metal CMP process, such as a CMP stop on dielectric process.

Referring to FIG. 2C and FIG. 2D, following formation of the fifth interconnect structure 234, the fourth conductive material 230 may be formed into fourth routing structures 236. For example, a sixth mask material 238 may be formed over and on the fourth conductive material 230, and the sixth mask material 238 may be patterned according to any of the manners described herein. Furthermore, the sixth mask material 238 may be utilized to form additional x-axis trenches and additional y-axis trenches within the control circuitry structure 202 and through the fourth conductive material 230, the twelfth insulative material 224, and the third routing structures 216 according to any of the manners described above in regard to FIG. 1N through FIG. 1R.

Additionally, a fourteenth insulative material 240 may be formed within the additional x-axis trenches and additional y-axis trenches and on and over the fourth routing structures 236. In some embodiments, the fourteenth insulative material 240 is formed of and includes a dielectric oxide material, such as SiOₓ (e.g., SiO₂). The fourteenth insulative material 240 may be substantially homogeneous, or the fourteenth insulative material 240 may be heterogeneous. An upper surface of the fourteenth insulative material 240 may be formed to be substantially planar. In some embodiments, the upper surface of the fourteenth insulative material 240 is formed vertically overlie the upper surfaces of the fourth routing structures 236.

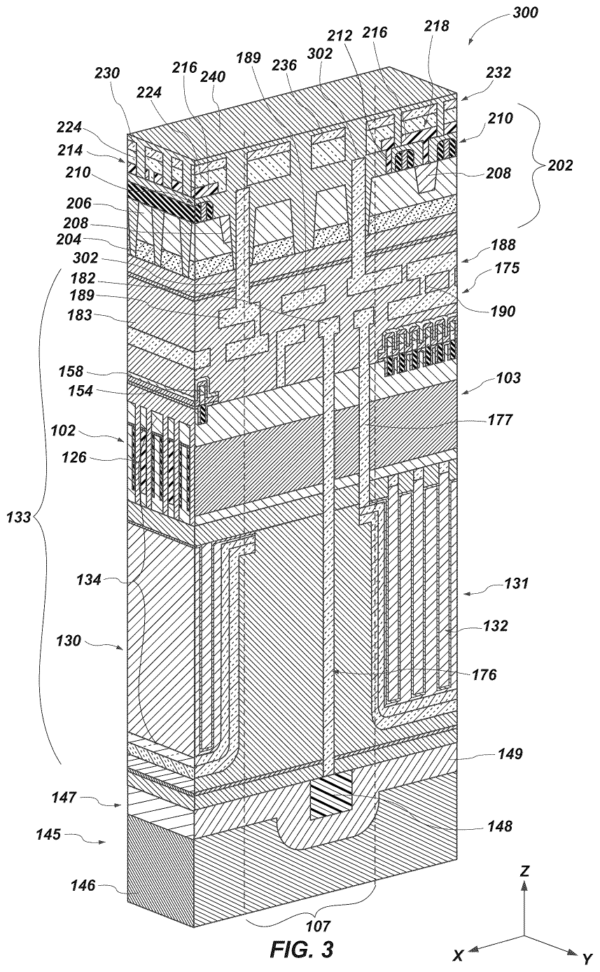

FIG. 3 is a simplified, perspective view of a microelectronic device 300 according to alternative embodiments of the disclosure. Similar to the microelectronic device 100 of FIG. 1A through FIG. 2D, the microelectronic devices 300 include a second assembly 133 having a first memory array structure 102, a second memory array structure 103, a first multi-storage node structure 130, a second multi-storage node structure 131, an RDL tier 127, a first shield structure 165, digit line structures 154, a second shield structure 166, first routing structures 182, third interconnect structures 190, second routing structures 189, and various insulative materials. The orientation of the foregoing structures may be the same or similar to the microelectronic device 100 described above in regard to FIG. 1A through FIG. 2D.

The microelectronic device 300 may further include diffusion structure 147 including a first doped region 148 and a second doped region 150 bonded to a side of the second assembly 133 proximate the first multi-storage node structure 130 and the second multi-storage node structure 131. Additionally, the microelectronic device 100 may include a first interconnect structure 176 extending vertically between and contacting (e.g., physically contacting, electrically contacting) a first routing structure 182 of the first routing tier 175 and the first doped region 148 of the diffusion structure 147. Likewise, the microelectronic device 100 may include at least one second interconnect structure 177 extending vertically between and contacting (e.g., physically contacting, electrically contacting) a first routing structure 182 of the first routing tier 175 and the second electrode 136 of a respective multi-storage node structure.

Moreover, the microelectronic device 100 may include a control circuitry structure 202 bonded to an opposite side of the second assembly 133. The control circuitry structure 202 may include a third routing tier 214 with third routing structures 216 and a fourth routing tier 232 with fourth routing structures 236 vertically overlying the third routing structures 216. Furthermore, the control circuitry structure 202 may include trenches and isolation structures 208 form within a second semiconductor material 206 and third base structure 204 of the control circuitry structure 202.

However, the microelectronic device 100 may include sixth interconnect structures 302 extending vertically from some of the third routing structures 216, through the at least some of the isolation structures 208 of the control circuitry structure 202, and to at least some of the second routing structures 189 of the second assembly 133. Some of the sixth interconnect structures 302 may be formed to extend vertically from some of the third routing structures 216 vertically overlying the control logic devices 218 to some of the second routing structures 189 and, as a result, the first routing structures 182, vertically underlying the control logic devices 218. One or more (e.g., each) of the sixth interconnect structures 302 may be formed to horizontally overlap and extend vertically through one or more of the isolation structures 208 (e.g., STI structures) of the control circuitry structure 202. Optionally, one or more other of the sixth interconnect structures 302 may be formed to horizontally overlap and extend vertically through the second semiconductor material 206 of the control circuitry structure 202.

Additionally, the microelectronic device 300 may not include a fifth interconnect structure 234 (FIG. 2B); rather, the control logic devices 218 of the control circuitry structures 202 and other devices and structures of the microelectronic device 300 may be operably connected to the first interconnect structure 176, and, as a result, the diffusion structure 147, through one or more routing structures (e.g., the first routing structures 182, the second routing structures 189, the third routing structures 216, and the fourth routing structures 236) and one or more interconnect structures (e.g., the first interconnect structure 176, the third interconnect structures 190, the fourth interconnect structures 212, and the sixth interconnect structure 302) of the second assembly 133 and the control circuitry structure 202. The diffusion structure 147 may operate according to any of the manners described above in regard to FIG. 1A through FIG. 2D.

Some embodiments include a microelectronic device comprising a first memory array structure comprising a first array region comprising first memory cells within a horizontal area thereof, the first memory cells respectively comprising a first access device and a first storage node device vertically underlying and coupled to the first access device, a second memory array structure comprising a second array region comprising second memory cells within a horizontal area thereof, the second memory cells respectively comprising a second access device and a second storage node device vertically underlying and coupled to the second access device, an edge of array region horizontally interposed between the first memory array structure and the second memory array structure, and a shared carrier structure over which the first memory array structure and the second memory array structure are oriented and attached. The shared carrier structure may include a diffusion structure comprising a first doped region of a first semiconductor material, the first doped region horizontally overlapping the edge of array region and a second doped region of the first semiconductor material, the second doped region horizontally neighboring the first doped region and at least partially surrounding outer, horizontal boundaries of the first doped region. The microelectronic device may further include a first interconnect structure in contact with the first doped region of the diffusion structure and extending vertically between a first routing structure of a first routing tier and the first doped region of the diffusion structure.

One or more embodiments include a method of forming a microelectronic device. The methods may include forming a first memory array structure and a second memory array structure, each of the first memory array structure and the second memory array structure comprising a respective array region having volatile memory cells within a horizontal area thereof, the volatile memory cells respectively comprising a vertical channel access device and a storage node device vertically underlying and coupled to the vertical channel access device, wherein the first memory array structure and the second memory array structure flank opposing horizontal sides of an edge of array region of the microelectronic device, forming a shared carrier structure, wherein forming the shared carrier comprises forming a diffusion structure comprising: forming a base structure; forming a first semiconductor material vertically overlying the base structure; doping a first region of the first semiconductor material to form a first doped region of the semiconductor material; doping a second region of the semiconductor material to a form a second doped region of the semiconductor material, the second doped region horizontally neighboring and contacting the first doped region; and bonding the shared carrier structure to a surface of the first memory array structure and the second memory array structure vertically closer to the storage node devices of the volatile memory cells than the vertical channel access devices of the volatile memory cells, and forming a first interconnect structure vertically overlapping with at least a portion of each of the first memory array structure and the second memory array structure and contacting the first doped region of the diffusion structure.

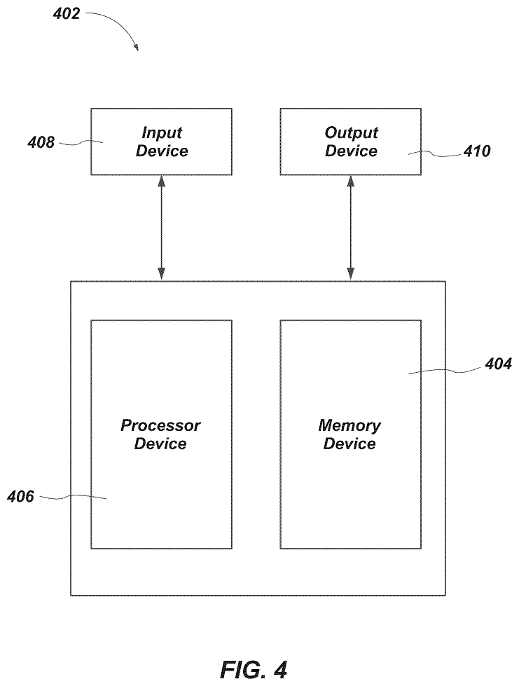

Microelectronic devices (e.g., the microelectronic device 100 (FIG. 2D)) in accordance with embodiments of the disclosure may be used in embodiments of electronic systems of the disclosure. For example, FIG. 4 is a block diagram illustrating an electronic system 402 according to embodiments of disclosure. The electronic system 402 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 402 includes at least one memory device 404. The memory device 404 may comprise, for example, a microelectronic device (e.g., the microelectronic device 100 (FIG. 1A)) previously described herein. The electronic system 402 may further include at least one electronic signal processor device 406 (often referred to as a “microprocessor”). The electronic signal processor device 406 may, optionally, comprise a microelectronic device (e.g., the microelectronic device 100 (FIG. 1A)) previously described herein. While the memory device 404 and the electronic signal processor device 406 are depicted as two (2) separate devices in FIG. 4, in additional embodiments, a single (e.g., only one) memory/processor device having the functionalities of the memory device 404 and the electronic signal processor device 406 is included in the electronic system 402. In such embodiments, the memory device 404/processor device 406 includes a microelectronic device (e.g., the microelectronic device 100 (FIG. 1A)) previously described herein. The electronic system 402 may further include one or more input devices 408 for inputting information into the electronic system 402 by a user, such as, for example, a mouse or other pointing device, a keyboard, a touchpad, a button, or a control panel. The electronic system 402 may further include one or more output devices 410 for outputting information (e.g., visual or audio output) to a user such as, for example, a monitor, a display, a printer, an audio output jack, a speaker, etc. In some embodiments, the input device 408 and the output device 410 include a single touchscreen device that can be used both to input information to the electronic system 402 and to output visual information to a user. The input device 408 and the output device 410 may communicate electrically with one or more of the memory device 404 and the electronic signal processor device 406.

Some embodiments include a microelectronic device comprising memory array structures individually comprising an array region comprising memory cells within a horizontal area thereof, the memory cells respectively comprising a vertically oriented access device and a storage node device vertically below and coupled to the vertically oriented access device, wherein neighboring memory array structures border opposing horizontal boundaries of an edge of array region of the microelectronic device, a control circuitry structure vertically above and dielectric-to-dielectric bonded to the memory array structures, a shared carrier structure over which the memory array structures are oriented and attached, the shared carrier structure comprising a diffusion structure comprising a first doped region of a semiconductor material, the first doped region horizontally overlapping the edge of array region and a second doped region of the semiconductor material, the second doped region horizontally neighboring the first doped region and at least partially surrounding outer, horizontal boundaries of the first doped region, a first interconnect structure in contact with the first doped region of the semiconductor material of the diffusion structure and extending vertically to a first routing structure of a first routing tier vertically above the memory array structures and below the control circuitry structure, and a second interconnect structure in contact with the first routing structure of the first routing tier and extending vertically to a second routing structure of a second routing tier vertically above the control circuitry structure.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. Any equivalent embodiments are within the scope of this disclosure. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described, will become apparent to those skilled in the art from the description. Such modifications and embodiments also fall within the scope of the appended claims and equivalents.

What is claimed is:

1. A microelectronic device, comprising:
a first memory array structure comprising a first array region comprising first memory cells within a horizontal area thereof, the first memory cells respectively comprising a first access device and a first storage node device vertically underlying and coupled to the first access device;
a second memory array structure comprising a second array region comprising second memory cells within a horizontal area thereof, the second memory cells respectively comprising a second access device and a second storage node device vertically underlying and coupled to the second access device;
an edge of array region horizontally interposed between the first memory array structure and the second memory array structure;
a diffusion structure over which the first memory array structure and the second memory array structure are oriented and attached, the diffusion structure comprising:
a first doped region of a first semiconductor material, the first doped region horizontally overlapping the edge of array region; and
a second doped region of the first semiconductor material, the second doped region horizontally neighboring the first doped region and at least partially surrounding outer, horizontal boundaries of the first doped region; and
a first interconnect structure in contact with the first doped region of the diffusion structure and extending vertically between a first routing structure of a first routing tier and the first doped region of the diffusion structure.

2. The microelectronic device of claim 1, further comprising a control circuitry structure vertically overlying and attached to the first memory array structure and the second memory array structure at boundaries of the first memory array structure and the second memory array structure vertically closer to the first access devices of the first memory cells and the second access devices of the second memory cells than to the first storage node devices of the first memory cells and the second storage node devices of the second memory cells.

3. The microelectronic device of claim 2, further comprising a second interconnect structure extending vertically between the first routing structure of the first routing tier contacting the first interconnect structure and a second routing structure of a second routing tier of the control circuitry structure.

4. The microelectronic device of claim 3, wherein the second interconnect structure vertically overlaps each of the first memory array structure, the second memory array structure, and the control circuitry structure.

5. The microelectronic device of claim 3, wherein horizontal boundaries of the second interconnect structure are at least substantially within the edge of array region.

6. The microelectronic device of claim 3, wherein the control circuitry structure comprises:
a second semiconductor material; and
at least one isolation structure extending vertically at least partially through the second semiconductor material,
wherein the second interconnect structure extends vertically through the at least one isolation structure.

7. The microelectronic device of claim 6, wherein the control circuitry structure comprises control logic devices formed on the second semiconductor material.

8. The microelectronic device of claim 1, wherein the first doped region is doped with one of an N-dopant or a P-dopant and the second doped region is doped with the other of an N-dopant or a P-dopant.

9. The microelectronic device of claim 1, further comprising:
a first cell plate vertically underlying the first memory array structure and forming an electrode of a first shared multi-capacitor structure; and
a second cell plate vertically underlying the second memory array structure and forming an electrode of a first shared multi-capacitor structure.

10. The microelectronic device of claim 9, further comprising at least one second interconnect structure in contact with a respective cell plate of the first cell plate and the second cell plate and extending vertically between another first routing structure of the first routing tier and the respective cell plate.

11. The microelectronic device of claim 1, wherein first doped region of the first semiconductor material of the diffusion structure is surrounded on three consecutive sides by the second doped region of the first semiconductor material.

12. A method of forming a microelectronic device, comprising:
forming a first memory array structure and a second memory array structure, each of the first memory array structure and the second memory array structure comprising a respective array region having volatile memory cells within a horizontal area thereof, the volatile memory cells respectively comprising a vertical channel access device and a storage node device vertically underlying and coupled to the vertical channel access device, wherein the first memory array structure and the second memory array structure flank opposing horizontal sides of an edge of array region of the microelectronic device;
forming a shared carrier structure, wherein forming the shared carrier comprises forming a diffusion structure comprising:
forming a base structure;
forming a first semiconductor material vertically overlying the base structure;
doping a first region of the first semiconductor material to form a first doped region of the semiconductor material;
doping a second region of the semiconductor material to a form a second doped region of the semiconductor material, the second doped region horizontally neighboring and contacting the first doped region; and
bonding the shared carrier structure to a surface of the first memory array structure and the second memory array structure vertically closer to the storage node devices of the volatile memory cells than the vertical channel access devices of the volatile memory cells; and
forming a first interconnect structure vertically overlapping with at least a portion of each of the first memory array structure and the second memory array structure and contacting the first doped region of the diffusion structure.

13. The method of claim 12, wherein bonding the shared carrier structure to the first memory array structure and the second memory array structure comprises bonding the shared carrier structure under the first memory array structure and the second memory array structure through dielectric-to-dielectric bonding between dielectric material of the first memory array structure and the second memory array structure and additional dielectric material of the shared carrier structure.

14. The method of claim 12, wherein forming the first interconnect structure comprises forming the first interconnect structure to extend vertically from an elevation above upper boundaries of the vertical channel access devices of the first memory array structure and the second memory array structure to the first doped region of the diffusion structure.

15. The method of claim 12, wherein forming the first interconnect structure comprises forming the first interconnect structure to be horizontally in-between the first memory array structure and the second memory array structure and within the edge of array region of the microelectronic device.

16. The method of claim 12, wherein forming the diffusion structure further comprises forming the first doped region of the first semiconductor material to be at least substantially surrounded on three consecutive sides by the second doped region of the first semiconductor material.

17. The method of claim 12, wherein bonding the shared carrier structure to the first memory array structure and the second memory array structure comprises bonding the shared carrier structure under the first memory array structure and the second memory array structure such that the first doped region of the first semiconductor material of the shared carrier structure horizontally overlaps with the edge of array region of the microelectronic device.

18. The method of claim 12, further comprising:
forming a control circuitry structure comprising control logic circuitry; and
bonding the control circuitry structure to another surface of the first memory array structure and the second memory array structure vertically closer to the vertical channel access devices of the volatile memory cells than the storage node devices of the volatile memory cells.

19. The method of claim 18, further comprising forming a second interconnect structure extending vertically through an isolation structure of the control circuitry structure and to a routing structure operably coupled to the first interconnect structure in contact with the first doped region of the first semiconductor material of the diffusion structure.

20. A microelectronic device, comprising:
memory array structures individually comprising an array region comprising memory cells within a horizontal area thereof, the memory cells respectively comprising a vertically oriented access device and a storage node device vertically below and coupled to the vertically oriented access device, wherein neighboring memory array structures border opposing horizontal boundaries of an edge of array region of the microelectronic device;
a control circuitry structure vertically above and dielectric-to-dielectric bonded to the memory array structures;
a diffusion structure over which the memory array structures are oriented and attached, the diffusion structure comprising:
a first doped region of a semiconductor material, the first doped region horizontally overlapping the edge of array region; and
a second doped region of the semiconductor material, the second doped region horizontally neighboring the first doped region and at least partially surrounding outer, horizontal boundaries of the first doped region;
a first interconnect structure in contact with the first doped region of the semiconductor material of the diffusion structure and extending vertically to a first routing structure of a first routing tier vertically above the memory array structures and below the control circuitry structure; and
a second interconnect structure in contact with the first routing structure of the first routing tier and extending vertically to a second routing structure of a second routing tier vertically above the control circuitry structure.
